(19) United States
(12) Patent Application Publication
(10) Pub. No.: US 2011/0006297 A1
(43) Pub. Date: Jan. 13, 2011

(54) PATTERNED CRYSTALLINE SEMICONDUCTOR THIN FILM, METHOD FOR PRODUCING THIN FILM TRANSISTOR AND FIELD EFFECT TRANSISTOR

(75) Inventors: Kazuyoshi Inoue, Chiba (JP); Koki Yano, Chiba (JP); Futoshi Utsuno, Chiba (JP); Masashi Kasami, Chiba (JP); Shigekazu Tomai, Chiba (JP); Hirokazu Kawashima, Chiba (JP)

Correspondence Address: MILLEN, WHITE, ZELANO & BRANIGAN, P.C., 2200 CLARENDON BLVD., SUITE 1400, ARLINGTON, VA, 22201, US

(73) Assignee: IDEMITSU KOSAN CO., LTD., Tokyo (JP)

(21) Appl. No.: 12/747,033

(22) PCT Filed: Nov. 14, 2008
(86) PCT No.: PCT/JP2008/070732

§ 371 Date: Jul. 19, 2010

(30) Foreign Application Priority Data
Dec. 12, 2007 (JP) 2007-321226
Jan. 17, 2008 (JP) 2008-008394
Jan. 17, 2008 (JP) 2008-008404

(51) Int. Cl. H01L 29/12; H01L 21/16

(52) U.S. Cl. 257/43; 438/104; 257/E21.078; 257/E29.068

(57) ABSTRACT

A patterned crystalline semiconductor thin film which is obtained by a method including: forming an amorphous thin film comprising indium oxide as a main component, crystallizing part of the amorphous thin film to allow the part to be semiconductive, and removing an amorphous part of the partially crystallized thin film by etching.

### TECHNICAL FIELD

The invention relates to a patterned crystalline semiconductor thin film. In particular, the invention relates to a patterned crystalline semiconductor thin film which can be produced without using a photoresist and can be directly patterned into a desired shape.

The invention also relates to a method for producing a thin film transistor having an oxidized film as a semiconductor film. In particular, the invention relates to a method for producing a thin film transistor having transistor properties which can be applied to displays or the like.

Further, the invention relates to a method for producing a thin film transistor. In particular, the invention relates to a method for producing a thin film transistor comprising the steps of forming a heat-receiving film and heating thereof.

### BACKGROUND ART

An oxide semiconductor film composed of a metal composite oxide has a high mobility and visible light transmission, and is used as a switching element, a driving circuit element or the like for a liquid crystal display, a thin film electroluminescence display, an electrophoresis display, a moving powder display, etc. Of the oxide semiconductor film formed of the above-mentioned metal composite oxide, an oxide semiconductor film formed of an indium oxide-gallium oxide-zinc oxide (IGZO) has been used most widely. In addition to this film, an oxide semiconductor film formed of indium oxide-zinc oxide (IZO), an oxide semiconductor film obtained by adding zinc oxide (ZTO) to tin oxide, an oxide semiconductor film obtained by adding gallium oxide to indium oxide-zinc oxide-tin oxide are known.

Oxide semiconductor films formed of these metal composite oxides are normally used after they are patterned. Specifically, a photoresist is applied to an intended oxide semiconductor film and the film is then patterned by exposing to light through a mask into a desired form. The patterned film is subjected to development, etching, resist peeling, rinsing or the like, whereby an oxide semiconductor film patterned into a desired shape can be produced. In addition to the above-mentioned method, it is possible to produce an oxide semiconductor film which is patterned into a desired shape by a method in which a photoresist is applied to a substrate, the photoresist is patterned into a desired shape by exposing to light through a mask and developed, an intended oxide semiconductor film to be patterned is formed thereon, the resist is peeled off, and a unnecessary portion of an oxide semiconductor is lifted off (Patent Documents 1 to 7).

However, these production methods using a photoresist suffered from problems that the surface of an oxide semiconductor film might be damaged by a resist-peeling agent and that the photoresist process itself was complicated to increase the production cost. Patent Document 8 discloses a method in which an oxide semiconductor film is crystallized to be semiconductive. Also in this method, a semiconductor film is formed by using lift off, mask sputtering or the like.

A field effect transistor is a device which is widely used as a unit electronic element of a semiconductor memory integrated circuit, a high-frequency signal amplification element, a liquid crystal driving element or the like. It is an electronic device which is most practically used in recent years.

Of field effect transistors, with a significant development in displays in recent years, not only in liquid crystal displays but also in various displays such as electroluminescence displays and field emission displays, a thin film transistor (TFT) has been widely used as a switching element for driving a display by applying a driving voltage to a display element.

As the material of a TFT, a silicon semiconductor is most widely used. In general, a silicon single crystal is used in a high-frequency amplification element, an integrated circuit element or the like, which require high-speed operation. In a liquid crystal driving element or the like, amorphous silicon is used to meet the requirement for an increase in area.

However, a crystalline silicon-based thin film is required to be heated at a high temperature, for example, 800° C. or higher, for crystallization. Therefore, it is difficult to form a crystalline silicon-based thin film on a glass substrate or on a substrate formed of an organic substance. Therefore, a crystalline silicon-based thin film could be formed only on an expensive substrate having a high thermal resistance such as silicon wafer and quartz. In addition, there was a problem that a large amount of energy and a large number of steps were required in production.

Further, since a crystalline silicon-based thin film is normally restricted to a TFT with a top-gate configuration, a reduction in production cost such as a decrease in number of masks was difficult.

On the other hand, an amorphous silicon semiconductor (amorphous silicon) which can be formed into a film at a relatively low temperature has a lower switching speed as compared with a crystalline silicon semiconductor. Therefore, when used as a switching element for driving a display, a problem may arise that a high-speed animation cannot be displayed.

Today, as a switching element for driving a display, a device using a silicon-based semiconductor film constitutes the mainstream due to various excellent performances including improved stability and processability of a silicon thin film and a high switching speed. Such a silicon-based thin film is generally produced by the chemical vapor deposition (CVD) method.

Some conventional thin film transistors (TFT) have an inverted-staggered structure in which, on a substrate formed of glass or the like, a gate electrode, a gate-insulating layer, a semiconductor film such as a hydrogenated amorphous silicon (a-Si:H) film, a source electrode and a drain electrode are stacked. This inverted-staggered type TFT is used, in a field of large-area devices including an image sensor, as a driving element for flat panel displays represented by active matrix-type liquid crystal displays. In these applications, with an improvement in function, an increase in operation speed is demanded even for conventional TFTs using amorphous silicon.

In particular, a transistor for driving an organic electroluminescence (EL) display is required to have the following properties.

(a) Less variation in properties such as threshold voltage even if driven for a long period of time
(b) Less variation in electronic properties so as to attain a uniform display screen
(c) Sufficient resistance to high-voltage driving of a multistage EL layer such as a multiphoton emission (MPE) structure

Conventional amorphous silicon TFTs satisfy the performance (b) and (c), but do not satisfy satisfactorily the performance (a). Polysilicon TFTs satisfy the performance (a), but do not satisfy satisfactorily the performance (b) and (e).

In order to overcome these defects, an attempt was made to form, on a gate insulating film, an amorphous silicon film, a buffer film and a light-heat conversion film in a sequential order, and to expose the light-heat conversion film to semiconductor laser light to cause the amorphous silicon film to be a finely crystalline silicon film (Patent Document 9).

However, since the temperature of amorphous silicon is required to be higher than the melting point (1410° C.) of silicon, there were problems such as occurrence of hillock when an Al-based material is used, selection of peripheral components is limited such as impossibility of using in a low-melting material, easy occurrence of thermal distribution which makes uniform heating difficult and restriction on heating apparatuses since a treatment takes a prolonged period of time unless a high power laser is used (Patent Document 10).

In recent years, as an alternative for a silicon-based semiconductor thin film, an oxide semiconductor thin film using an oxide has attracted attention.

Of the transparent semiconductor thin films formed of these metal oxides, in particular, transparent semiconductor thin film obtained by crystallizing zinc oxide at a higher temperature has a lower field effect mobility of about 1 cm²/V·sec and has a small on-off ratio. In addition, since current leakage tends to occur easily, practical application on the industrial scale was difficult. Many studies have been made on an oxide semiconductor containing a crystalline substance using zinc oxide. If film formation is conducted by a sputtering method which is generally conducted on the industrial scale, the following problems occurred.

That is, a TFT might have deteriorated performance such as a low mobility, a small on-off ratio, a large amount of current leakage, unclear pinch-off and tendency of becoming normally-on. In addition, due to poor chemicals resistance, the production process or the use environment was limited such as difficulty in wet etching. Further, in order to improve the performance, film formation was required to be conducted at a higher pressure, which caused industrial application to be difficult due to a lower film-forming speed and a higher treatment temperature of 700° C. or higher. Further, TFT performance such as field mobility in a bottom-gate configuration was poor. In order to improve the performance, the film thickness was required to be 50 nm or more in a top-gate configuration, which restricted the TFT device configuration (Patent Document 11). In addition, an attempt was made to increase the resistance of a conductive amorphous oxide film to allow it to be a crystalline semiconductor film, whereby a field effect transistor was produced (Patent Document 8). This method, however, encountered problems such as the need of a large-sized heating furnace due to a prolonged crystallization time and difficulty in uniform crystallization of a large area. Further, an attempt was made to improve the crystalline properties of a crystalline oxide semiconductor by heating a gate electrode (Patent Document 12). In this method, since heating was conducted through a gate insulating film, problems such as deterioration of a gate insulating film, occurrence of current leakage, impossibility of uniform heating or the like occurred.

A field effect transistor such as a thin film transistor (TFT) is widely used as a unit electronic element of a semiconductor memory integrated circuit, a high-frequency signal amplification element, a liquid crystal driving element or the like. It is an electronic device which is most practically used recently. Of these, with a remarkable development of displays in recent years, a TFT is widely used as a switching element which serves to drive a display by applying a driving voltage to a display device in various displays such as liquid crystal displays (LCD), electroluminescence displays (EL) and field emission displays (FED).

As the material for the semiconductor layer (active layer, channel layer) which is a primary member of a field effect transistor, a silicon semiconductor is most widely used. In general, for a high-frequency amplification element, an integrated circuit element or the like, which require high-speed operation, silicon single crystals are used. On the other hand, for a liquid crystal driving element or the like, an amorphous silicon semiconductor (amorphous silicon) is used in order to satisfy the requirement for an increase in area.

For example, thin film transistors (TFT) having an inverted-staggered structure in which, on a substrate formed of glass or the like, a gate electrode, a gate insulating layer, a semiconductor film such as a hydrogenated amorphous silicon (a-Si:H) film, a source electrode and a drain electrode are stacked are known. This inverted-staggered type TFT is used, in a field of large-area devices including an image sensor, as a driving element for flat panel displays such as active matrix-type liquid crystal displays. In these applications, an increase in operation speed is demanded with an improvement in function even for conventional TFTs using amorphous silicon.

Today, as the switching element for driving a display, a device using a silicon-based semiconductor film constitutes the mainstream since it has many improved performance such as improved stability or processability of a silicon thin film and a high switching speed. These silicon-based thin films are generally produced by the chemical vapor deposition (CVD) method.

However, a crystalline silicon-based thin film is heated at a high temperature, for example, 800° C. or higher, for crystallization. Therefore, it is difficult to form a crystalline silicon-based thin film on a glass substrate or on a substrate formed of an organic substance. Therefore, a crystalline silicon-based thin film can be formed only on an expensive substrate having a high thermal resistance such as silicon wafer and quartz. In addition, it has a problem that a large amount of energy and a large number of steps are required in production. Further, since the application of a crystalline silicon-based thin film is normally restricted to a TFT with a top-gate configuration, a reduction in production cost such as a decrease in number of masks is difficult.

On the other hand, an amorphous silicon thin film which can be formed into a film at a relatively low temperature has a lower switching speed as compared with a crystalline silicon-based thin film. Therefore, when used as a switching element for driving a display, a problem may arise that a high-speed animation cannot be displayed. Further, when a semiconductor active layer is irradiated with visible rays, it exhibits conductivity, and current leakage may occur to cause malfunction, resulting in a deteriorated performance as a switching element. Therefore, a method is known to provide a shielding layer to shield visible rays. As the shielding layer, a thin metal film is known.

However, if a light-shielding layer formed of a thin metal film is provided, not only the production steps are increased but also a problem arises that, since a thin metal film has a floating potential, the light-shielding layer is required to be fixed to ground level, which results in generation of parasitic capacitance. Under such circumstance, in recent years, an oxide semiconductor thin film using an oxide having more improved stability than a silicon-based semiconductor thin film has attracted attention.

Patent Document 11 discloses a TFT which uses zinc oxide as a semiconductor layer. This semiconductor layer, however, had a field effect mobility as low as 1 cm²/V·sec and a small on-off ratio. Further, since current leakage tended to generate easily, practical application on the industrial scale was difficult.

Many studies have been made on an oxide semiconductor containing crystals of zinc oxide. If film formation is conducted by a sputtering method which is generally conducted on the industrial scale, the following problems may occur. That is, a TFT may have deteriorated performance such as a low mobility, a small on-off ratio, a large amount of current leakage, unclear pinch-off and tendency of becoming normally-on. In addition, since an oxide semiconductor containing crystals of zinc oxide have poor chemicals resistance, the production process or the use environment was limited such as difficulty in wet etching. Further, in order to improve the performance of an oxide semiconductor containing crystals of zinc oxide, film formation was required to be conducted at a higher pressure, which caused industrial application to be difficult due to a lower film-forming speed and a higher treatment temperature exceeding 700° C. Further, TFT performance such as field mobility in a bottom-gate configuration was poor. In order to improve the performance, the film thickness was required to be 50 nm or more in a top-gate configuration, which restricted the TFT device structure.

In order to solve the above-mentioned problem, a TFT using an amorphous oxide semiconductor film formed of indium oxide and zinc oxide has been studied (Patent Document 13). This amorphous oxide semiconductor film had a problem a sufficient on-off ratio could not be obtained due to a high off current.

In Patent Document 14, studies are made on application of a composite oxide containing indium, zinc and gallium atoms which has heretofore been studied as a transparent conductive film, to a TFT. However, in the case of a TFT using a semiconductor film formed of this composite oxide, in order to allow it to be a stable TFT in which the S value is kept small and a shift in threshold value caused by stress is small, it was required to conduct a heat treatment to meet this requirement (for example, a heat treatment for 1 hour or longer at a high temperature exceeding 350° C. (Patent Document Nos. 15 and 5, and Non-Patent Document 1). When a TFT substrate for displays is mass-produced using a large-sized glass substrate, the substrate treatment speed is an important factor which determines the production amount. Such heat treatment imposed a heavy burden on time or facilities, and lowered productivity to hinder practical application.

Various heating methods including a laser annealing method have been studied as a method for melt crystallization of a silicon-based semiconductor or as a method for increasing crystalline properties of a crystalline oxide semiconductor (Patent Document 9). However, as compared with a silicon semiconductor, an amorphous oxide film has a high light transmission, and hence, it was difficult to subject it to a heat treatment using energy rays. Accordingly, as for the heat treatment method of an amorphous oxide film, almost no studies were made except for heating it at a temperature of a furnace or the like (Patent Document 12).

Patent Document 1: JP-A-2006-165527

Patent Document 2: JP-A-2006-165528

Patent Document 3: JP-A-2006-165529

Patent Document 4: JP-A-2006-165530

Patent Document 5: JP-A-2006-165531

Patent Document 6: JP-A-2006-165532

Patent Document 7: JP-A-2006-173580

Patent Document 8: WO2007/058248

Patent Document 9: JP-A-2007-5508

Patent Document 10: JP-A-2007-35964

Patent Document 11: JP-A-2003-86808

Patent Document 12: JP-A-2007-123861

Patent Document 13: US-A-2005/0199959

Patent Document 14: JP-A-2000-44236

Patent Document 15: JP-A-2007-311404

Non-patent Document 1: Kim, Chang Jung at al. Highly stable Ga2O3—In2O3—ZnO TFT for Active-Matrix Organic Light-Emitting Diode Display Application, Electron Devices Meeting, 2006. IEDM '06. International (ISBN: 1-4244-0439-8)

A first object of the invention is to provide a patterned crystalline semiconductor thin film which can be produced without using a photoresist and of which the pattern can be directly formed into a desired shape.

A second object of the invention is, in view of the above-mentioned circumstances, to produce at a temperature not higher than the melting point of silicon a thin film transistor which has a high resistance to pressure and suffers only a slight variation in properties even if driven for a long time.

A third object of the invention is to provide a thin film transistor using a stable amorphous oxide semiconductor which can be formed by heat-treating an amorphous oxide film easily and quickly and of which the S value is rendered small to minimize a shift in threshold value by stress.

### DISCLOSURE OF THE INVENTION

According to a first aspect of the invention, the following patterned crystalline semiconductor thin film or the like is provided.

1. A patterned crystalline semiconductor thin film which is obtained by a method comprising:

forming an amorphous thin film comprising indium oxide as a main component,

crystallizing part of the amorphous thin film to allow the part to be semiconductive, and

removing an amorphous part of the partially crystallized thin film by etching.

2. The patterned crystalline semiconductor thin film according to 1, wherein the amorphous thin film comprises indium oxide containing a positive divalent metal oxide.
3. The patterned crystalline semiconductor thin film according to 1, wherein the amorphous thin film comprises indium oxide containing a positive trivalent metal oxide.
4. The patterned crystalline semiconductor thin film according to 1, wherein the amorphous thin film comprises indium oxide containing a positive divalent metal oxide and a positive trivalent metal oxide.
5. The patterned crystalline semiconductor film according to any one of 1 to 4, wherein the crystallization is conducted by using an electron beam.
6. The patterned crystalline semiconductor film according to any one of 1 to 4, wherein the crystallization is conducted by using a laser beam.
7. The patterned crystalline semiconductor film according to 5 or 6, wherein the method further comprises conducting a heat treatment after the etching.

According to a second aspect of the invention, the following method for producing a thin film transistor and the following field effect transistor can be provided.

8. A method for producing a thin film transistor comprising the steps of:

forming an amorphous oxide film,

forming a light-heat conversion film on the amorphous oxide film, and

irradiating the light-heat conversion film with an energy ray to allow at least part of the amorphous oxide film to be semiconductive.

9. The method for producing a thin film transistor according to 8, wherein the amorphous oxide film is conductive, and when at least part of the amorphous oxide film is allowed to be semiconductive by irradiating the light-heat conversion film with an energy ray, the part is crystallized.
10. The method for producing a thin film transistor according to 8 or 9, which further comprises the step of patterning the amorphous oxide film to form a source electrode and a drain electrode.
11. The method for producing a thin film transistor according to 8 or 9, which further comprises the step of patterning the light-heat conversion film to form a source electrode and a drain electrode.
12. The method for producing a thin film transistor according to any one of 8 to 10, which further comprises the step of removing the light-heat conversion film.
13. The method for producing a thin film transistor according to any one of 8 to 12, which further comprises the step of providing a buffer film between the amorphous oxide film and the light-heat conversion film.
14. The method for producing a thin film transistor according to any one of 8 to 13, wherein the energy ray is semiconductor laser light or lamp light.
15. The method for producing a thin film transistor according to any one of 8 to 14, wherein the amorphous oxide film comprises at least In.
16. The method for producing a thin film transistor according to any one of 8 to 14, wherein the amorphous oxide film comprises a composite metal oxide which contains In, and a positive divalent element or a positive trivalent element.
17. A field effect transistor comprising:

a gate electrode,

a layer which is on the gate electrode and is formed of a source electrode, a drain electrode and a semiconductor film, and

a buffer film and a light-heat conversion film which are on the semiconductor film, wherein

the semiconductor film is a film which is obtained by crystallizing an oxide which forms the source electrode and the drain electrode.

18. A field effect transistor comprising:

a source electrode and a drain electrode,

a semiconductor film which is on the source electrode and the drain electrode, and comprises a crystalline oxide,

a gate insulating film which is on the semiconductor film, and

a gate electrode which is on the gate insulating film.

According to a third aspect of the invention, the following method for producing a thin film transistor and the like are provided.

19. A method for producing a thin film transistor which comprises the steps of:

forming an amorphous oxide film,

forming a heat-receiving film, and

heating the heat-receiving film.

20. The method for producing a thin film transistor according to 19, which further comprises the step of patterning the heat-receiving film to form at least one of a source electrode, a drain electrode and a gate electrode.
21. The method for producing a thin film transistor according to 19 or 20, which further comprises the step of stacking a buffer layer and the step of removing the heat-receiving film and the buffer layer.
22. The method for producing a thin film transistor according to any one of 19 to 21, wherein the heat-receiving film is heated by a heating method selected from the group consisting of infrared lamp heating, ultraviolet lamp heating, semiconductor laser heating, excimer laser heating, an electromagnetic induction heating and plasma jet heating.
23. The method for producing a thin film transistor according to any one of 19 to 22, wherein the heat treatment of the amorphous oxide film is conducted at a temperature equal to or higher than the film forming temperature of the amorphous oxide film, and equal to or lower than the crystallization temperature of the amorphous oxide film.
24. The method for producing a thin film transistor according to any one of 19 to 23, wherein the amorphous oxide film comprises one or more elements selected from the group consisting of In, Zn and Sn.
25. A thin film transistor which is obtained by the method for producing a thin, film transistor according to any one of 19 to 24.

According to the first aspect of the invention, a patterned crystalline semiconductor thin film which can be produced without a photoresist and of which the pattern can be directly formed into a desired shape is provided.

According to the method for producing a thin film transistor which is the second aspect of the invention, the following can be attained without heating at a temperature not lower than the melting point of silicon: a small variation in properties such as threshold voltage even when driven for a long period of time; a small variation in electric properties so as to attain a uniform display screen; and capability of sufficiently withstanding a pressure which is applied even when a multistage EL layer such as a MPE (muitiphoton emission) structure is driven at a higher voltage.

According to the third aspect of the invention, it is possible to provide a thin film transistor using a stable amorphous oxide semiconductor which can be formed by heat-treating an amorphous oxide film easily and quickly and of which the S value is rendered small to minimize a shift in threshold value by stress.

### BRIEF DESCRIPTION OF THE DRAWINGS

FIG. 1 is a photograph showing the surface of an Si wafer having a thin film which was irradiated with an electron beam in Example 1;

FIG. 2 is a photograph showing the surface of a patterned crystalline thin film produced in Example 1;

FIG. 3A is a view showing a step of the method for producing a transistor of Embodiment 1 in the second aspect of the invention;

FIG. 3B is a view showing a step of the method for producing a transistor of Embodiment 1 in the second aspect of the invention;

FIG. 3C is a view showing a step of the method for producing a transistor of Embodiment 1 in the second aspect of the invention;

FIG. 3D is a view showing a step of the method for producing a transistor of Embodiment 1 in the second aspect of the invention;

FIG. 3E is a view showing a step of the method for producing a transistor of Embodiment 1 in the second aspect of the invention;

FIG. 3F is a view showing a step of the method for producing a transistor of Embodiment 1 in the second aspect of the invention;

FIG. 3G is a view showing a step of the method for producing a transistor of Embodiment 1 in the second aspect of the invention;

FIG. 3H is a view showing a step of the method for producing a transistor of Embodiment 1 in the second aspect of the invention;

FIG. 4A is a view showing a step of the method for producing a transistor of Embodiment 2 in the second aspect of the invention;

FIG. 4B is a view showing a step of the method for producing a transistor of Embodiment 2 in the second aspect of the invention;

FIG. 4C is a view showing a step of method for producing a transistor of Embodiment 2 in the second aspect of the invention;

FIG. 4D is a view showing a step of the method for producing a transistor of Embodiment 2 in the second aspect of the invention;

FIG. 4E is a view showing a step of the method for producing a transistor of Embodiment 2 in the second aspect of the invention;

FIG. 4F is a view showing a step of the method for producing a transistor of Embodiment 2 in the second aspect of the invention;

FIG. 4G is a view showing a step of the method for producing a transistor of Embodiment 2 in the second aspect of the invention;

FIG. 4H is a view showing a step of the method for producing a transistor of Embodiment 2 in the second aspect of the invention;

FIG. 5A is a view showing a step of the method for producing a transistor of Embodiment 3 in the second aspect of the invention;

FIG. 5B is a view showing a step of the method for producing a transistor of Embodiment 3 in the second aspect of the invention;

FIG. 5C is a view showing a step of the method for producing a transistor of Embodiment 3 in the second aspect of the invention;

FIG. 5D is a view showing a step of the method for producing a transistor of Embodiment 3 in the second aspect of the invention;

FIG. 5E is a view showing a step of the method for producing a transistor of Embodiment 3 in the second aspect of the invention;

FIG. 5F is a view showing a step of the method for producing a transistor of Embodiment 3 in the second aspect of the invention;

FIG. 5G is a view showing a step of the method for producing a transistor of Embodiment 3 in the second aspect of the invention;

FIG. 5H is a view showing a step of the method for producing a transistor of Embodiment 3 in the second aspect of the invention;

FIG. 6A is a view showing a step of the method for producing a transistor of Embodiment 4 in the second aspect of the invention;

FIG. 6B is a view showing a step of the method for producing a transistor of Embodiment 4 in the second aspect of the invention;

FIG. 6C is a view showing a step of the method for producing a transistor of Embodiment 4 in the second aspect of the invention;

FIG. 6D is a view showing a step of the method for producing a transistor of Embodiment 4 in the second aspect of the invention;

FIG. 6E is a view showing a step of the method for producing a transistor of Embodiment 4 in the second aspect of the invention;

FIG. 6F is a view showing a step of the method for producing a transistor of Embodiment 4 in the second aspect of the invention;

FIG. 6G is a view showing a step of the method for producing a transistor of Embodiment 4 in the second aspect of the invention;

FIG. 6H is a view showing a step of the method for producing a transistor of Embodiment 4 in the second aspect of the invention;

FIG. 6I is a view showing a step of the method for producing a transistor of Embodiment 4 in the second aspect of the invention;

FIG. 7A is a view showing a step of the method for producing a transistor of Embodiment 5 in the second aspect of the invention;

FIG. 7B is a view showing a step of the method for producing a transistor of Embodiment 5 in the second aspect of the invention;

FIG. 7C is a view showing a step of the method for producing a transistor of Embodiment 5 in the second aspect of the invention;

FIG. 7D is a view showing a step of the method for producing a transistor of Embodiment 5 in the second aspect of the invention;

FIG. 7E is a view showing a step of the method for producing a transistor of Embodiment 5 in the second aspect of the invention;

FIG. 7F is a view showing a step of the method for producing a transistor of Embodiment 5 in the second aspect of the invention;

FIG. 7G is a view showing a step of the method for producing a transistor of Embodiment 5 in the second aspect of the invention;

FIG. 7H is a view showing a step of the method for producing a transistor of Embodiment 5 in the second aspect of the invention;

FIG. 8A is a view showing a step of the method for producing a transistor of Embodiment 6 in the second aspect of the invention;

FIG. 8B is a view showing a step of the method for producing a transistor of Embodiment 6 in the second aspect of the invention;

FIG. 8C is a view showing a step of the method for producing a transistor of Embodiment 6 in the second aspect of the invention;

FIG. 8D is a view showing a step of the method for producing a transistor of Embodiment 6 in the second aspect of the invention;

FIG. 8E is a view showing a step of the method for producing a transistor of Embodiment 6 in the second aspect of the invention;

FIG. 8F is a view showing a step of the method for producing a transistor of Embodiment 6 in the second aspect of the invention;

FIG. 8G is a view showing a step of the method for producing a transistor of Embodiment 6 in the second aspect of the invention;

FIG. 8H is a view showing a step of the method for producing a transistor of Embodiment 6 in the second aspect of the invention;

FIG. 8I is a view showing a step of the method for producing a transistor of Embodiment 6 in the second aspect of the invention;

FIG. 8J is a view showing a step of the method for producing a transistor of Embodiment 6 in the second aspect of the invention;

FIG. 8K is a view showing a step of the method for producing a transistor of Embodiment 6 in the second aspect of the invention;

FIG. 8L is a view showing a step of the method for producing a transistor of Embodiment 6 in the second aspect of the invention;

FIG. 8M is a view showing a step of the method for producing a transistor of Embodiment 6 in the second aspect of the invention;

FIG. 9A is a view showing a step of the method for producing a transistor of Embodiment 7 in the second aspect of the invention;

FIG. 9B is a view showing a step of the method for producing a transistor of Embodiment 7 in the second aspect of the invention;

FIG. 9C is a view showing a step of the method for producing a transistor of Embodiment 7 in the second aspect of the invention;

FIG. 9D is a view showing a step of the method for producing a transistor of Embodiment 7 in the second aspect of the invention;

FIG. 9E is a view showing a step of the method for producing a transistor of Embodiment 7 in the second aspect of the invention;

FIG. 9F is a view showing a step of the method for producing a transistor of Embodiment 7 in the second aspect of the invention;

FIG. 10 is a view showing a lamp used in Example 24;

FIG. 11 is a view showing steps of the method for producing for a thin film transistor (bottom-gate type) of the first embodiment in the third aspect of the invention;

FIG. 12 is a view showing steps of the method for producing a method for a thin film transistor (bottom-gate type) of the second embodiment in the third aspect of the invention;

FIG. 13 is a view showing steps of the method for producing a method for a thin film transistor (top-gate type) of the third embodiment in the third aspect of the invention;

FIG. 14 is a view showing steps of the method for producing a method for a thin film transistor (top-gate type) of the fourth embodiment in the third aspect of the invention;

FIG. 15 is a view showing one embodiment in the third aspect in which, after the heat-receiving film in the third aspect is patterned, the patterned heat-receiving film is heated to allow it serve as an electrode, whereby a thin film transistor is produced; and

FIG. 16 is a schematic cross-sectional view of switching elements 6 and 7 obtained by forming a protective film 18 and a pixel electrode 32 in a thin film transistor 1 of Embodiment 1 and a thin film transistor 2 of Embodiment 2 in the third aspect.

### BEST MODE FOR CARRYING OUT THE INVENTION

### I. First Aspect

The patterned crystalline semiconductor thin film of the invention is obtained by forming an amorphous thin film comprising indium oxide as a main component, crystallizing part of the amorphous thin film to allow the part to be semiconductive, and removing an amorphous part of the partially crystallized thin film by etching. In this way, the patterned crystalline semiconductor thin film of the invention can be produced without using a photoresist and can be directly patterned into a desired shape.

The amorphous thin film comprising indium oxide as a main component can be easily formed, for example, by sputtering a target having a desired composition. In the invention, the amorphous thin film comprising indium oxide as a main component means an amorphous thin film comprising 50 wt % or more of indium oxide.

It is preferred that the amorphous thin film which comprises indium oxide as a main component be formed of indium oxide containing a positive divalent metal oxide. Due to the presence of a positive divalent metal oxide, when the amorphous thin film is crystallized, it can be semiconductive more easily.

As examples of the positive divalent metal oxide, an oxide of one or more metals selected from the group consisting of Zn, Mg, Ni and Cu can be given, for example. Preferred oxides are ZnO, MgO, NiO or CuO.

In the case where the amorphous thin film which comprises indium oxide as a main component is formed of indium oxide containing a positive divalent metal oxide, if the metal component of the positive divalent metal oxide is taken as M2, an atomic ratio of indium and M2 in the amorphous thin film, i.e. M2/(In+M2), is preferably 0.0001 to 0.1, more preferably 0.0005 to 0.05, and further preferably 0.001 to 0.05.

If the atomic ratio M2/(In+M2) is less than 0.0001, the amorphous thin film may not be semiconductive easily. On the other hand, if the atomic ratio. M2/(In+M2) exceeds 0.1, the amorphous thin film may not be crystallized, and hence may not be semiconductive. In addition, a part formed in a desired shape may be removed by etching conducted later.

The amorphous thin film which comprises indium oxide containing a positive divalent metal oxide has an advantage that, when crystallized, a divalent metal ion is solid-soluted in a crystallized indium oxide, whereby electron carriers generated by oxygen deficiency of indium oxide can be suppressed to control the carrier concentration in an optimum range. The optimum carrier concentration is 10E12 cm⁻³ to 10E17 cm⁻³, for example, and preferably 10E14 cm⁻² to 10E17 cm⁻³.

It is preferred that the amorphous thin film which comprises indium oxide as a main component be formed of indium oxide containing a positive trivalent metal oxide. Due to the presence of a positive trivalent metal oxide, when the amorphous thin film is crystallized, it can be semiconductive more easily.

As the above-mentioned positive trivalent metal oxide, an oxide of a positive trivalent metal having an ionic radius which is the same as or close to the ionic radius of indium (±25% of the ionic radius of indium) may be selected in respect of easiness of crystallization. An oxide of a positive trivalent metal having an ionic radius which is within ±20% of the ionic radius of indium is preferable. Such positive trivalent metal oxide does not inhibit crystallization of the amorphous thin film.

As examples of the above-mentioned positive trivalent metal oxide, an oxide of one or more metals selected from the group consisting of B, Al, Ga, Sc, Y and a lanthanoid-based element can be given, for example. Preferred examples of the above-mentioned lanthanoid-based element include Sm, Ho, Lu, La, Nd, Eu, Gd, Er or Yb.

In the case where the amorphous thin film which comprises indium oxide as a main component is formed of indium oxide containing a positive trivalent metal oxide, if the metal component of the positive trivalent metal oxide is taken as M3, an atomic ratio of indium and M3 in the amorphous thin film, i.e. M3/(In+M3), is preferably 0.0001 to 0.2, more preferably 0.0005 to 0.15, and further preferably 0.001 to 0.1.

If the atomic ratio M3/(In+M3) is less than 0.0001, the crystalline thin film may not be semiconductive easily. On the other hand, if the atomic ratio M3/(In +M3) exceeds 0.2, the amorphous thin film may not be crystallized, and hence may not be semiconductive. In addition, a part which has been formed in a desired shape may be removed by etching conducted later. In addition, the mobility of a crystalline semiconductor thin film obtained by crystallizing an amorphous thin film with an atomic ratio M3/(In+M3) exceeding 0.2 may be too small.

The crystalline thin film which comprises indium oxide containing a positive trivalent metal oxide has an advantage that a positive trivalent metal oxide can suppress the oxygen deficiency itself of indium oxide, thereby to control the carrier concentration to an optimum range. The optimum carrier concentration is 10E12 cm⁻³ to 10E17 cm⁻³, for example, and preferably 10E14 cm⁻³ to 10E17 cm⁻³.

It is preferred that the amorphous thin film which comprises indium oxide as a main component be formed of indium oxide containing positive divalent metal oxide and a positive trivalent metal oxide. Due to the presence of both of the positive divalent oxide and the positive trivalent oxide, when the amorphous thin film is crystallized, it can be semiconductive more easily.

As mentioned above, the positive divalent metal oxide and the positive trivalent metal oxide function differently in the crystalline thin film. Specifically, in the case of the positive divalent metal oxide, a positive divalent metal ion is solid-soluted in crystallized indium oxide, whereby electron carriers generated by the oxygen deficiency of indium oxide can be suppressed. On the other hand, the positive trivalent metal oxide can suppress the oxygen deficiency itself of indium oxide. In the invention, since the amorphous thin film contains both the positive divalent metal oxide and the positive trivalent metal oxide, the electron carrier generation can be synergistically suppressed. By containing both the positive divalent metal oxide and the positive trivalent metal oxide, as compared with the case where one of these metal oxides is contained singly, effects can be obtained even if the content is small.

In the invention, the amorphous thin film may essentially consist of indium oxide, and optionally, a positive divalent metal oxide and/or a positive trivalent metal oxide. The amorphous thin film may consist only of these components. Here, the “essentially consist of” means that the amorphous thin film consists of indium oxide, and optionally, a positive divalent metal oxide and/or a positive trivalent metal oxide, and may contain, in addition to these components, the following components.

The amorphous thin film may contain, as far as it does not impair the advantageous effects of the invention (semiconductor properties, in particular), an oxide of a metal with an atomic valency of positive tetravalency or higher. As examples of an oxide of a metal with an atomic valency of positive tetravalency or higher, GeO₂, SnO₂, TiO₂, ZrO₂, HfO₂, CeO₂, Nb₂O₅, Ta₂O₅, MoO₃ and WO₃ can be given, for example.

If the amorphous thin film contains the oxide of a metal with an atomic valency of positive tetravalency or higher as mentioned above, the content of the oxide of a metal with an atomic valency of positive tetravalency or higher is normally 10 wt % or less, preferably 5 wt % or less, and more preferably 3 wt % or less.

Preferably, the amorphous thin film is crystallized by means of an electron beam or a laser light. By irradiating the amorphous thin film which comprises indium oxide as a main component with an electron beam or laser light, the amorphous thin film can be crystallized to be semiconductive easily.

If an electron beam is used for crystallization, as the electron beam to be used, an accelerated electron beam with an output power of 5 kV to 1000 kV can be used. As for the irradiation method, the entire surface of a desired shape can be irradiated with an electron beam all at once, or it is possible to partially conduct irradiation while changing the irradiation position to allow the irradiated surface to be in a desired shape. The irradiation time is normally 1 second to 120 minutes, preferably 10 seconds to 30 minutes. If the irradiation time is less than 1 second, the film may not be crystallized. If the irradiation time exceeds 120 minutes, productivity may be lowered to increase the production cost.

If laser light is used for crystallization, as the laser light to be used, laser light with an output power of 100 mW to 1 kW can be used, for example. As for the irradiation method, the entire surface of a desired shape can be irradiated with an electron beam all at once, or it is possible to partially conduct irradiation while changing the irradiation position to allow the irradiated surface to be in a desired shape.

As for the type of laser light to be used, laser light capable of applying energy necessary for crystallization may be appropriately selected. For example, an infrared laser such as a YAG laser, a green laser and a carbon dioxide laser; a semiconductor laser, a dye laser, an excimer laser or the like can be used.

Of the above-mentioned laser light, specifically, a KrF excimer laser with an irradiation wavelength of 248 nm or an ArF excimer laser with a wavelength of 193 nm can be used. When pulse irradiation is conducted with these excimer lasers, it is preferred that the frequency of irradiation be set to 2 to 2000 times, the pulse width be set to 5 nsec. to 100 nsec. and the beam size be set to 10 μm×10 μm or 1 mm×1 mm so as to narrow the beam width.

The energy density of the surface irradiated with laser light is normally 10 mJ/cm² to 1000 mJ/cm², preferably 50 mJ/cm² to 500 mJ/cm². If the energy density of the irradiated surface is less than 10 mJ/cm², the time required for crystallization may be too long. On the other hand, if the energy density of the irradiated surface exceeds 1000 mJ/cm², due to the excessively large energy density, problems may arise that the amorphous thin film evaporates and the crystallized thin film is damaged.

The patterned crystalline semiconductor thin film of the invention can be obtained by removing by etching an amorphous part of the thin film, a part of which has been crystallized into a desired shape. The amorphous thin film part and the crystalline semiconductor thin film part differ in etching speed. Specifically, while the amorphous thin film part is etched at a higher speed, the crystalline semiconductor film part is etched at a very low speed due to crystallization. By utilizing such difference in etching speed, only the amorphous thin film part is selectively etched, whereby a patterned crystalline semiconductor thin film with a desired shape can be obtained.

As the etching solution to be used, a weak acid such as an organic acid is normally used. Specifically, an organic acid such as acetic acid, oxalic acid and propionic acid can be used. Preferably, an aqueous solution of these organic acids is used.

The concentration of an aqueous solution of an organic acid is normally 0.1 to 10 wt %, preferably 1 to 5 wt %. If the concentration of an aqueous solution of an organic acid is less than 0.1 wt %, the etching speed may be too slow. On the other hand, if the concentration of an aqueous solution of an organic acid exceeds 10 wt %, etching may proceeds too fast to cause the crystalline semiconductor part to be also etched, resulting in difficulty in formation of a patterned crystalline semiconductor film with a desired shape.

The temperature of an etching solution during etching is normally 10° C. to 60° C., preferably 20° C. to 50° C. If the temperature of an etching solution is less than 10° C., the etching speed may be slow. If the temperature of an etching solution exceeds 60° C., the water content of an etching solution may evaporate, causing difficulty in keeping the concentration of an organic acid constant.

As the etching solution, in addition to an organic acid, an aqueous solution of an acid such as hydrochloric acid, hydrobromic acid, hydroiodic acid, sulfuric acid, nitric acid and phosphoric acid can also be used. If an etching solution other than an aqueous solution of an organic acid, such as the above-mentioned aqueous solution, is used, the concentration and the temperature may be appropriately selected. Further, a mixture of these aqueous solutions can also be used.

The patterned crystalline semiconductor thin film obtained by the above-mentioned etching is preferably further subjected to a heat treatment. By further subjecting the patterned crystalline semiconductor thin film to a heat treatment after the etching of the amorphous part, it is possible to improve the crystalline properties of the crystalline part, whereby a crystalline semiconductor thin film without an amorphous part (irregularity in crystals in the crystal-grain boundary part) can be obtained. If a crystalline semiconductor thin film with an amorphous part (irregularity in crystals in the crystal-grain boundary part) being remained is used in a thin film transistor or the like, the off current may be increased, the on-off ratio may be decreased and the threshold voltage may be varied during driving.

Although a heat treatment may be conducted in air, in an inert gas such as nitrogen and under vacuum, in respect of the production cost, it is preferred that a heat treatment be conducted in air. The heat treatment temperature is normally set within a range of 150° C. to 450° C., preferably within a range of 200° C. to 300° C. If the heat treatment temperature is less than 150° C., crystallization may not proceed. If a heat treatment temperature exceeds 450° C., the substrate may be deformed due to its insufficient heat resistance. The heat treatment time is normally 1 minute to 12 hours, preferably 10 minutes to 60 minutes. If the heat treatment time is less than 1 minute, crystallization may not proceed. If a heat treatment temperature time exceeds 12 hours, the production cost may be increased.

The thickness of the patterned crystalline semiconductor thin film obtained by the above-mentioned process is normally 5 to 500 nm, preferably 10 to 200 nm, and more preferably 15 to 100 nm. If the thickness of the crystalline semiconductor thin film is less than 5 nm, the crystalline semiconductor thin film may not be a thin film and may have a sea-island pattern. If the thickness of the crystalline semiconductor thin film exceeds 500 nm, when the crystalline semiconductor thin film of the invention is used as a thin film transistor, the mobility thereof may be lowered and the threshold value thereof may be too large.

### II. Second Aspect

The method for producing a thin film transistor of the invention comprises the steps of forming an amorphous oxide film, forming a light-heat conversion film on the amorphous oxide film, and irradiating the light-heat conversion film with an energy ray to allow at least part of the amorphous oxide film to be semiconductive.

In the invention, when the light-heat conversion film is irradiated with an energy ray, the light-heat conversion film converts the energy ray (light) to heat, and the heat is transmitted to the amorphous oxide film below the light-heat conversion film, whereby the amorphous oxide film becomes semiconductive, and the amorphous oxide film becomes a semiconductor (crystalline) film. The light-heat conversion film may be then removed. As mentioned above, since the amorphous oxide film is allowed to be semiconductive by using the light-heat conversion film, a transistor can be produced without heating at a temperature higher than the melting point of silicon.

The amorphous nature of the amorphous oxide film can be judged by the absence of a specific peak in an X-ray diffraction. Crystallization of the amorphous oxide film can be judged by the presence of the specific peak in an X-ray diffraction.

It is preferred that the specific resistance of the amorphous oxide film having conductivity be 10⁻⁵ to 10⁻² Ωcm, with 10⁻⁵ to 10⁻³ Ωcm being particularly preferable. If the specific resistance exceeds 10⁻² Ωcm, it may be difficult to use the part thereof as an electrode. It is preferred that the specific resistance of the semiconductor film be 10⁻² to 10⁸ Ωcm, further preferably 10⁻¹ to 10⁶ Ωcm, with 10⁰ to 10⁴ Ωcm being particularly preferable. If the specific resistance is smaller than 10⁻² Ωcm, the off current may be higher when used in a TFT. A specific resistance exceeding 10⁸ Ωcm may result in a lowered mobility.

For forming the amorphous oxide film and the light-heat conversion film, a chemical film formation method or a physical film formation method can be used without restrictions. Of these, a DC, AC or RF sputtering method is preferable. It is more preferable to form a film by a DC or AC sputtering method.

As compared with RF sputtering, DC or AC sputtering causes less damage during film formation. Therefore, when used in a field effect transistor, effects such as a decreased shift in threshold voltage, improved mobility, a reduced threshold voltage and a decreased S value can be expected.

The light-heat conversion film can be formed from wiring materials such as Mo and Mo alloys (Mo—W, Mo—Ta or the like), Cu and Cu alloys (Cu—Mn, Cu—Mo, Cu—Mg), Al and Al alloys (Al—Nd, Al—Ce, Al—Zr or the like), Ag and Ag alloys, Cr and Cr alloys, and Ta and Ta alloys, a metal having a high melting point such as Ti, V, Nb, Hf or DLC, oxides, nitrides, carbides, oxynitrides or the like. It is preferred that the light-heat conversion film be formed of Mo and an Mo alloy (Mo—W, Mo—Ta or the like), Cu and a Cu alloy (Cu—Mn), Al and an Al alloy (Al—Nd, Al—Ce, Al—Zr or the like), or Ag and an Ag alloy.

The amorphous oxide film preferably comprises at least In. More preferably, the amorphous oxide film comprises In as a main component.

If it, contains an indium element, the content of the indium element relative to all atoms excluding oxygen in the amorphous oxide film is preferably 87 at % or more and 100 at % or less, and more preferably 90 at % or more and 99 at % or less. If the content of the indium element is less than 90 at %, not only the crystallization temperature of the crystalline film may be increased, but also the mobility of the resulting thin film transistor may be lowered.

It is preferred that the amorphous oxide film be formed of a composite oxide which contains two or more elements other than oxygen. For example, the amorphous oxide film is formed of a composite metal oxide containing In, and a positive divalent element or a positive trivalent element.

It is preferred that the amorphous oxide film contain a divalent metal element. The divalent metal element is an element which can take an atomic valency of positive divalency in the ionic state. If the crystalline film contains indium which is a positive trivalent metal element, and further contains a positive divalent metal element, electrons generated by oxygen deficiency can be suppressed, whereby carrier density can be kept low.

Examples of the positive divalent metal element include Zn, Be, Mg, Ca, Sr, Ba, Ti, V, Cr, Mn, Fe, Co, Ni, Pd, Pt, Cu, Ag, Cd, Hg, Sm, Eu and Yb. In respect of effective control of carrier concentration, Zn, Mg, Mn, Co, Ni, Cu and Ca are preferable.

Of the above-mentioned preferable positive divalent metal elements, in respect of carrier control effects by the addition, Cu and Ni are more preferable. In respect of transmittance and the width of a band gap, Zn and Mg are more preferable.

These divalent metal elements may be used in combination of two or more as far as they do not impair the advantageous effects of the invention.

If the amorphous oxide film contains an indium element and a positive divalent metal element, the atomic ratio [X/(X+In)] of indium [In] to the positive divalent metal element [X] is preferably 0.0001 to 0.13.

If the atomic ratio [X/(X+In)] is less than 0.0001, the number of carriers may not be controlled since the content of the divalent metal element is small. On the other hand, if the atomic ratio [X/(X+In)] exceeds 0.13, problems may arise that the interface between the crystalline film and the amorphous film or the surface of the crystalline film may be denatured easily and become unstable, the crystallization temperature of the crystalline film may be higher to make crystallization difficult, the carrier concentration may be increased, the hall mobility may be lowered, the threshold voltage may be varied when a transistor is driven, and the driving may be unstable.

If the amorphous oxide film contains indium oxide and an oxide of a divalent metal element, the total mass of indium oxide and the oxide of a divalent metal element is normally 50 mass %, preferably 65 mass % or more, more preferably 80 mass % or more, still more preferably 90 mass % or more and particularly preferably 95 mass % or more relative to the mass of the crystalline film. If the total mass of indium and the oxide of a divalent metal element is less than 50 mass %, the mobility of the oxide semiconductor film may be lowered or other problems occur, thereby preventing the advantageous effects of the invention from being sufficiently exhibited.

The amorphous oxide film may contain a positive trivalent metal element other than indium. The positive trivalent metal element means an element which can take an atomic valency of positive trivalency in the ionic state.

Examples of the positive trivalent metal element include Ga, Al, La, Ce, Pr, Nd, Pm, Sm, Eu, Gd, Tb, Dy, Ho, Er, Tm, Yb and Lu. Two or more positive trivalent metal elements may be contained.

If the amorphous oxide film further contains a slight amount of a tetravalent metal element such as Sn, since the positive divalent metal element such as Zn is well-balanced in valency number relative to indium, which is a trivalent metal element, the crystalline film can be preferably stabilized. However, if the crystalline film contains a large amount of a tetravalent metal element, the carrier density may become too large, causing the off current to be increased when used in a thin film transistor. The content of the tetravalent metal element is preferably 0.01 at % to 10 at % of the positive trivalent metal element contained in the amorphous oxide film.

If the content of the tetravalent metal element is defined by mass, the content of the tetravalent metal element is preferably 3 mass % or less, more preferably 2 mass % or less and particularly preferably 1 mass % or less, relative to the mass of the entire amorphous oxide film. If the content of the tetravalent metal element exceeds 3 mass %, the carrier density may not be controlled to low.

For example, if the crystalline film contains at least one element selected from the group consisting of indium, zinc (positive divalent metal element), gallium (positive trivalent metal element) and tin (positive tetravalent metal element), a high mobility can be realized. The mobility of the crystalline film can be controlled by adjusting the partial oxygen pressure in an atmospheric gas during the formation of the crystalline film, and the contents of H₂O and H₂ in an atmospheric gas.

It is preferred that the crystalline film show a bixbyite crystal structure of indium. The hall mobility can be increased when the crystalline film has a bixbyite crystal structure. The bixbyite crystal structure can be confirmed by X-ray diffraction.

It is preferred that the semiconductor film have an electron carrier concentration of 10¹³ to 10¹⁸/cm³, more preferably 10¹⁴ to 10¹⁷/cm³. If the electron carrier concentration exceeds 10¹⁸/cm³, a transistor may have a higher off current. If the electron carrier concentration is smaller than 10¹³/cm³, the mobility of a transistor may be lowered.

It is preferred that the specific resistance of the semiconductor film be 10⁻² to 10⁸ Ωcm, more preferably 10⁻¹ to 10⁶ Ωcm, and further preferably 10⁰ to 10⁴ Ωcm. If the specific resistance is smaller than 10⁻² Ωcm, a transistor may have a higher off current. If the specific resistance exceeds 10⁸ Ωcm, the mobility of a transistor may be lowered.

It is preferred that the semiconductor film have a band gap of 2.0 to 6.0 eV, more preferably 2.8 to 4.8 eV. If the band gap is smaller than 2.0 eV, visible rays may be absorbed to cause a filed effect transistor to malfunction. If the specific resistance is larger than 6.0 eV, a field effect transistor may not function.

It is preferred that the semiconductor film be a nbndegenerate semiconductor which shows thermal activity. If the semiconductor film is a degenerate semiconductor, the off current/gate leakage current may be increased due to an excessive amount of carriers, or the threshold value may become negative to cause a transistor to be normally-on.

The surface roughness (RMS) of the semiconductor film is preferably 1 nm or less, more preferably 0.6 nm, with 0.3 nm or less being particularly preferable. If the surface roughness is larger than 1 nm, the mobility may be lowered.

The film thickness of the semiconductor film is normally 0.5 to 500 nm, preferably 1 to 150 nm, more preferably 3 to 80 nm, and particularly preferably 10 to 60 nm. If the film thickness is smaller than 0.5 nm, it is difficult to form an uniform film on the industrial scale. On the other hand, if the film thickness is larger than 500 nm, the film forming time is prolonged, thereby making industrial application impossible. If the film thickness is within a range of 3 to 80 nm, TFT properties such as the mobility and the on-off ratio are particularly preferable.

The production method of the invention may comprise a step of patterning the amorphous oxide film to form a source electrode or a drain electrode. It is possible to directly pattern a conductive amorphous oxide film to form an electrode. Also, it is possible to form an electrode by irradiating a non-conductive amorphous oxide film with light with a short wavelength, for example, before or after the patterning to lower the resistance thereof. Directly patterning of a conductive amorphous oxide film to form an electrode is preferable since the number of steps can be reduced.

If a conductive light-heat conversion film is used, the method may comprise a step of patterning the light-heat conversion film to form a source electrode and a drain electrode.

Wet etching, dry etching or the like can be used in such patterning.

The production method of the invention may comprise a step of providing a buffer film between the amorphous oxide film and the light-heat conversion film. Due to the provision of a buffer film, the temperature distribution during a heat treatment can be uniform.

As the buffer layer, a common buffer layer can be used arbitrarily as far as it does not impair the advantageous effects of the invention. For example, SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these, SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable. The oxygen number of these oxides may not necessarily coincide with the stoichiometrical ratio (for example, they may be SiO₂ or SiOx). Of these, oxides are particularly preferable. If they are oxides, it is possible to prevent oxygen from entering the buffer layer when heated. Such a buffer layer may be a stack structure in which two or more different layers are stacked. The buffer layer may be crystalline, polycrystalline or amorphous. It is preferred that the buffer layer be polycrystalline or amorphous since it can be produced easily on the industrial scale.

The buffer layer may be removed together with the light-heat conversion film or may be left.

As the energy ray, semiconductor laser light, lamp light or the like may be used. Lamp heating (lamp rapid thermal anneal, LRTA) and semiconductor laser heating are preferable since uniform heating is possible. Lamp heating which can heat a large area is particularly preferable. The heating temperature of the amorphous oxide film is preferably 200 to 1400° C.

As for the wavelength of light to be irradiated, it is preferable to use a wavelength in the ultraviolet region, the visible region or the infrared region. It is more preferable to use a wavelength in a wavelength region of 100 nm to 2400 nm.

As the lamp light, it is preferable to use lamp light with a wavelength in the visible region or the infrared region. It is more preferable to use a wavelength in a wavelength region of 400 nm to 2400 nm.

The lamp heating (LRTA) can be conducted by radiation from one or a plurality of lamps selected from a halogen lamp, a metal halide lamp, a xenon arc lamp, a carbon arc lamp, a high-pressure sodium lamp and a high-pressure mercury lamp.

If laser beam irradiation is conducted, it is possible to use beam from a continuous oscillation type laser (CW laser beam) or beam from a pulse oscillation type laser (pulse laser beam). By irradiating fundamental waves of a laser beam or the second to fourth harmonic wave of these fundamental waves, it is possible to attain good crystalline properties. It is preferable to use laser light having energy larger than the band gap of the oxide semiconductor film. For example, laser light emitted from an excimer laser oscillator such as KrF, ArF, XeCl or XeF is used.

The production method of the invention will be explained below in more detail.

In the production method of the invention, for example, a gate electrode is formed on a substrate, a gate insulating film is formed on the gate electrode and an amorphous oxide film and a light-heat conversion film are formed on the gate insulating film. The light-heat conversion film is irradiated with an energy ray to allow at least part of the amorphous oxide film to be semiconductive. Thereafter, the light-heat conversion film is patterned to form a source electrode and a drain electrode.

Further, in the production method of the invention, for example, a gate electrode is formed on a substrate, a gate insulating film is formed on the gate electrode, and an amorphous oxide film and a light-heat conversion film are formed on the gate insulating film. Thereafter, the light-heat conversion film is irradiated with an energy ray to allow at least part of the amorphous oxide film below the light-heat conversion film to be semiconductive, and part of the amorphous oxide film which is not allowed to be semiconductive is used as a source electrode and a drain electrode.

Further, in the production method of the invention, for example, a gate electrode is formed on a substrate, a gate insulating film is formed on the gate electrode, and an amorphous oxide film and a light-heat conversion film are formed on the gate insulating film. Thereafter, the light-heat conversion film is irradiated with an energy ray to allow the amorphous oxide film below the light-heat conversion film to be semiconductive. Simultaneously, part of the amorphous oxide film which is not below the light-heat conversion film is caused to have a lower resistance to form a source electrode and a drain electrode.

Further, in the production method of the invention, for example, a gate electrode is formed on a substrate, a gate insulating film is formed on the gate electrode, and an amorphous oxide film and a light-heat conversion film are formed on the gate insulating film. Thereafter, the light-heat conversion film is irradiated with an energy ray to allow the amorphous oxide film to be semiconductive. Part of the amorphous oxide film which has become semiconductive is caused to have a lower resistance to form a source electrode and a drain electrode.

Further, in the production method of the invention, for example, a source electrode and a drain electrode are formed on a substrate and an amorphous oxide film and a light-heat conversion film are formed on the source electrode and the drain electrode. Thereafter, the light-heat conversion film is irradiated with an energy ray to allow the amorphous oxide film to be semiconductive. An insulating layer and a gate electrode are formed on the amorphous oxide film which has become semiconductive.

There are no particular restrictions on the substrate. Substrates which are commonly used can be arbitrarily selected as far as they do not impair the advantageous effects of the invention. For example, glass substrates such as those formed of non-alkaline glass, soda-lime glass and quartz glass or resin substrates such as those formed of polyethylene terephthalate (PET), polyamide and polycarbonate (PC), or a metal thin film (foil) substrate can be used. A single crystal substrate such as an Si substrate is difficult to be increased in size, and may cause the production cost to be increased.

There are no particular restrictions on the material for forming each of the gate electrode, the source electrode and the drain electrode. Materials which are commonly used can be arbitrary used as far as they do not impair the advantageous effects of the invention. For example, transparent electrodes such as indium tin oxide (ITO), indium zinc oxide, ZnO and SnO₂, metal electrodes such as Al, Ag, Cr, Ni, Mo, Au, Ti and Ta, or metal electrodes of alloys containing these metals can be used. In addition, it is preferred that two or more of these be stacked to decrease contact resistance or to improve interfacial strength. Further, in order to decrease the contact resistance of the source electrode and the drain electrode, the interface between the semiconductor film and the electrode is subjected to a plasma treatment, an ozone treatment or the like to adjust the resistance. As for the composition excluding oxygen, it is preferred that the source electrode and the drain electrode have the same composition as that of the semiconductor film.

It is preferred that the gate electrode be self-aligned with the source/drain electrode. If the gate electrode is not self-aligned with the source/drain electrode, the overlapping of the gate electrode and the source/drain electrode may vary due to an error in mask alignment. If the overlapping of the gate electrode and the source/drain electrode varies, the capacitance between them may vary, thereby causing uneven display in a display.

There are no particular restrictions on the material for forming the gate insulating film. Materials which are commonly used can be arbitrary used as far as they do not impair the advantageous effects of the invention.

For example, SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these, SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable. The oxygen number of these oxides may not necessarily coincide with the stoichiometrical ratio (for example, they may be SiO₂ or SiOx).

The gate insulating film may be a stack structure in which two or more different insulating films are stacked. The gate insulating film may be crystalline, polycrystalline or amorphous. It is preferred that the gate insulating film be polycrystalline or amorphous since it can be produced easily on the industrial scale.

It is preferred that the semiconductor film be protected by a passivation layer. There are no particular restrictions on the material for forming the passivation layer of the semiconductor. Materials which are commonly used can be arbitrary used as far as they do not impair the advantageous effects of the invention. For example, SiO₂, SiNx, Al₂O₃, Ta₂O₅, TiO₂, MgO, ZrO₂, CeO₂, K₂O, Li₂O, Na₂O, Rb₂O, Sc₂Oₐ, Y₂O₃, Hf₂O₃, CaHfO₃, PbTi₃, BaTa₂O₆, SrTiO₃, AlN or the like may be used. Of these, SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable. The oxygen number of these oxides may not necessarily coincide with the stoichiometrical ratio (for example, they may be SiO₂ or SiOx).

The protective film may be a stack structure in which two or more different insulating films are stacked. The protective film may be crystalline, polycrystalline or amorphous. It is preferred that the protective film be polycrystalline or amorphous since it can be produced easily on the industrial scale.

It is preferred that the thin film transistor have a structure capable of shielding the semiconductor film from light. If it does not have a structure capable of shielding the semiconductor film from light (light-shielding layer), carrier electrons may be excited when exposed to light, resulting in an increased off current. As the light-shielding layer, a thin film having a large absorption at a wavelength equal to or smaller than 500 nm can be used. The light-shielding layer may be positioned above or below the semiconductor film. However, it is preferred that the light-shielding layer be provided both above and below the semiconductor film. The gate insulating film, a black matrix or the like may be used as the light-shielding layer. If the light-shielding layer is provided on only either above or below, it is required to contrive the structure in order not to allow light to be irradiated from the side on which no light-shielding layer is provided.

The ratio (W/L) of the channel width W and the channel length L of the thin film transistor is normally 0.1 to 100, preferably 1 to 20 and particularly preferably 2 to 8. If the W/L exceeds 100, the current leakage may be increased or the on-off ratio may be decreased. If the W/L is smaller than 0.1, the field effect mobility may be lowered or the pinch off may be unclear.

Further, the channel length L is normally 0.1 to 1000 μm, preferably 1 to 100 μm, more preferably 2 to 10 μm. If the channel length is less than 0.1 μm, it is difficult to produce the transistor on the industrial scale, and the current leakage may be increased. A channel length exceeding 1000 μm is not preferable since it makes the device too large in size.

The mobility of the thin film transistor is preferably 1 cm²/Vs or more, more preferably 3 cm²/Vs or more, and particularly preferably 8 cm²/Vs or more. If the mobility is smaller than 1 cm²/Vs, the switching speed may be too slow to be used in a large-area, high-precise display.

The on-off ratio is preferably 10⁶ or more, more preferably 10⁷ or more, and particularly preferably 10⁸ or more.

The off current is preferably 2 pA or less, more preferably 1 pA or less.

The gate leakage current is preferably 1 pA or less.

The threshold voltage is preferably 0 to 4 V, more preferably 0 to 3 V, and particularly preferably 0 to 2 V. If the threshold voltage is smaller than 0, the transistor may become normally-on, and a voltage may be required to be applied when the transistor is in the off state, which may increase consumption power. If the threshold voltage is larger than 5 V, the driving voltage may be increased, resulting in an increase in consumption power.

The S value is preferably 0.8 V/dec or less, more preferably 0.3 V/dec or less, still more preferably 0.25 V/dec or less, and particularly preferably 0.2 V/dec or less. If the S value is larger than 0.8 V/dec, the driving voltage may be too large to increase the consumption power. In particular, when used in an organic EL display, which is driven by DC, it is particularly preferable to allow the S value to be 0.3 V/dec or less since the consumption power can be significantly decreased.

The shift amount in threshold voltage before and after the application of a direct voltage of 3 μA at 60° C. for 100 hours is preferably 1.0 V or less, more preferably 0.5 V or less. If the shift amount exceeds 1 V, the image quality may be deteriorated when used in a transistor of an organic EL display.

It is preferred that hysteresis when the gate voltage is increased or decreased in a transmission curve or a variation in threshold voltage when measured in air (variation in surrounding atmosphere) be small.

It is preferred that the thin film transistor of the invention have a coplanar structure. A coplanar transistor means a transistor in which the gate electrode and the source/drain electrode are on the same side of the semiconductor film, the semiconductor film and the source/drain electrode are on the same plane, or the semiconductor film and the source/drain electrode are not in contact with each other on a surface which is in parallel with the substrate. The inverted type of a transistor is called a staggered transistor. In the case of a staggered transistor, since an electric field is applied in a curved manner, a trap may be generated in the semiconductor interface or the gate insulating film, whereby the transistor properties such as mobility, threshold voltage and S value may be deteriorated. In addition, contact resistance may be generated in the interface between the semiconductor film and the source/drain electrode, transistor properties such as mobility, threshold voltage, S value and hysteresis may be lowered.

As long as it is of coplanar structure, the transistor may have any of the conventional structures such as a top-gate type structure and a bottom-gate type structure. In the case of a bottom-gate type structure, it is preferred that the semiconductor film be protected by a passivation layer.

### Embodiment 1

### Bottom-Gate Type Transistor

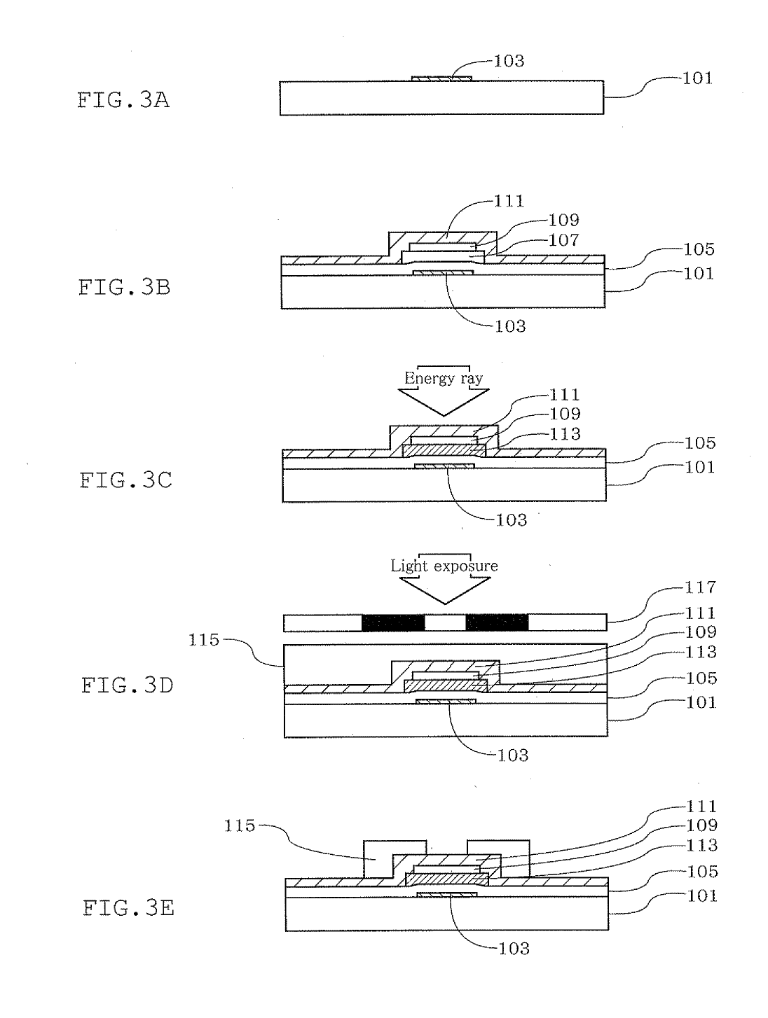

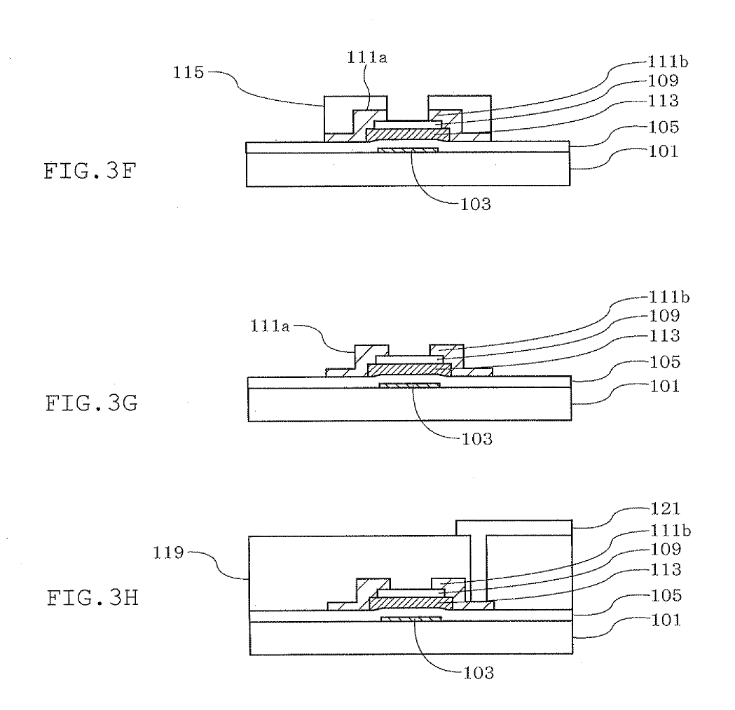

FIGS. 3A to 3H each show a step of the method for producing a thin film transistor (hereinafter simply referred to as a transistor) of Embodiment 1

A gate electrode 103 is formed on a substrate 101 (FIG. 3A). Further, a gate insulating film 105, an amorphous oxide film 107, a buffer film 109 and a heat-light conversion film 111 are formed thereon (FIG. 3B). Subsequently, an energy ray is irradiated, and the ray is then converted to heat by the heat-light conversion film 111. This heat is transmitted through the buffer film 109, the amorphous oxide film 107 below the buffer film 109 is allowed to be semiconductive (crystallized) to be a semiconductor film 113 (FIG. 3C). The semiconductor film 113 serves as the active layer of a TFT. Thereafter, a resist 115 is applied, and the resultant is exposed to light through a mask 117 (FIG. 3D). Then, the resist 115 is developed and removed (FIG. 3E). Subsequently, etching is conducted to form a source electrode 111a and a drain electrode 111b (FIG. 3F), and the resist 115 is peeled off (FIG. 3G). As shown in FIG. 3H, the sealing by a protective film 119 is preferred. In FIG. 3H, a pixel electrode 121 is connected to the drain electrode 111b through the protective film 119. Without the protective film, the properties may be adversely affected by a process environment or an environment during use, and hence, deteriorated.

When the semiconductor layer which has been subjected to a heat treatment is used in a TFT, the film suffers less variation in properties, such as a variation in threshold voltage, even if direct current is flown for a long period of time. The reason therefor is considered as follows. The structure of the semiconductor layer is stabilized due to crystallization by heat treatment, and as a result, a lesser amount of oxygen is moved by heat generated at the time of driving.

Since a variation in properties such as a change in threshold voltage does not occur even if a direct current is flown for a long period of time, unevenness in a display screen caused by the screen display history (current history) hardly occurs.

In addition, since a variation in properties such as a change in threshold voltage does not occur even if a direct current is flown for a long period of time, it can be used in a case where a multistage EL layer with a MPE (multiphoton emission) structure or the like is driven at a higher voltage.

### Embodiment 2

### Bottom-Gate Type Transistor

This embodiment differs from Embodiment 1 in that a protective film covering the amorphous oxide film is not formed.

FIGS. 2A to 2H each show a step of the method for producing a transistor of Embodiment 2.

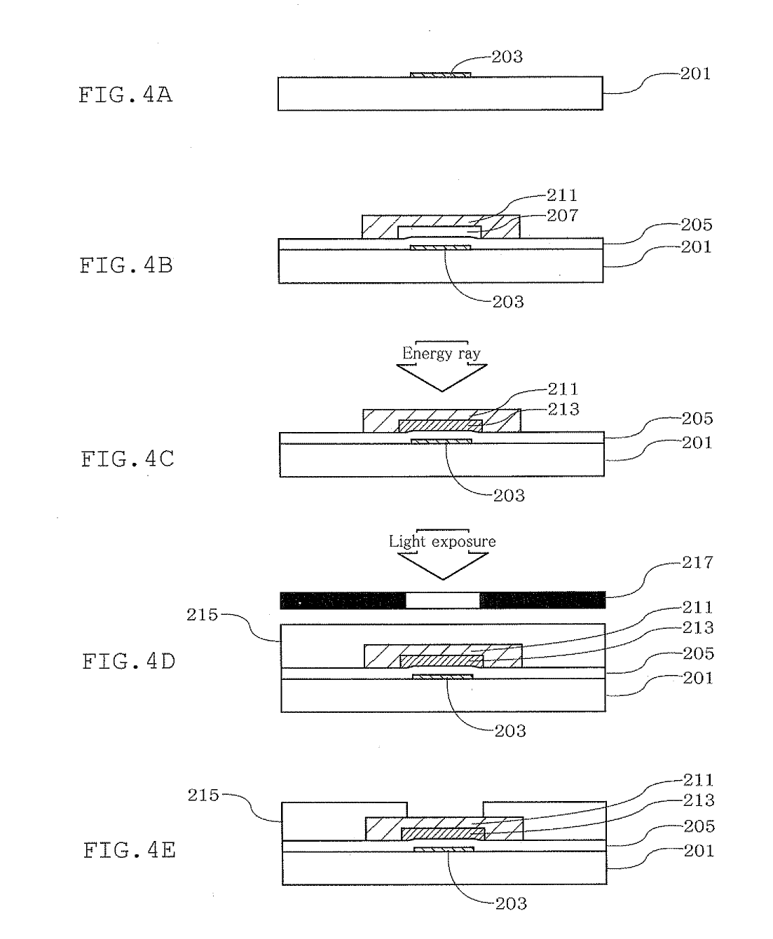

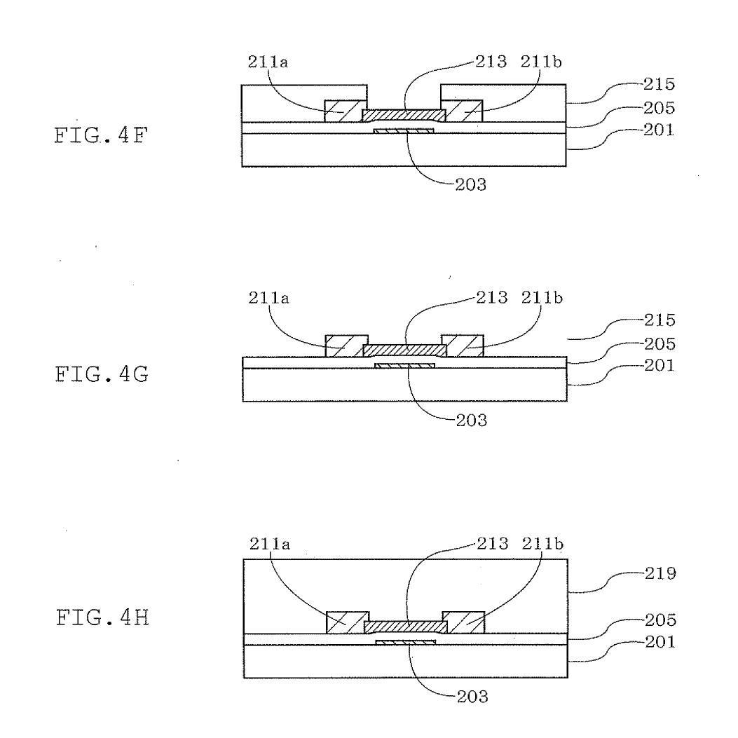

In the same manner as in Embodiment 1, a gate electrode 203 is formed on a substrate 201 (FIG. 4A). Subsequently, a gate insulating film 205, an amorphous oxide film 207 and a heat-light conversion film 211 are formed thereon (FIG. 4B). Subsequently, by irradiating an energy ray, the amorphous oxide film 207 is allowed to be semiconductive (crystallized) to form a semiconductor film 213 (FIG. 4C). Thereafter, a resist 215 is applied, and the resultant is exposed to light through a mask 217 (FIG. 4D). The resist 215 is developed and removed (FIG. 4E). Subsequently, etching is conducted to form a source electrode 211a and a drain electrode 211b (FIG. 4F), and the resist 215 is peeled off (FIG. 4G). A protective film 219 is formed in the same manner as in Embodiment 1 (FIG. 4H).

### Embodiment 3

### Bottom-Gate Type Transistor

In this embodiment, a buffer film and a light-heat conversion film are provided. After heating the light-heat conversion film by an energy ray, the buffer film and the light-heat conversion film are removed together. The light-heat conversion film is provided only on a part which is desired to be semiconductive.

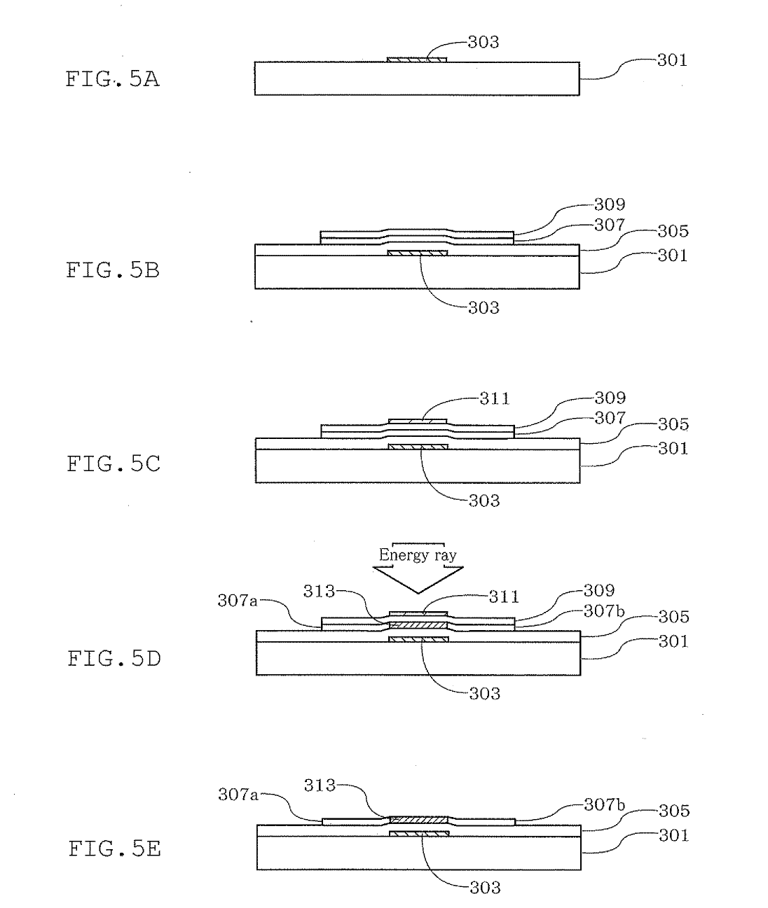

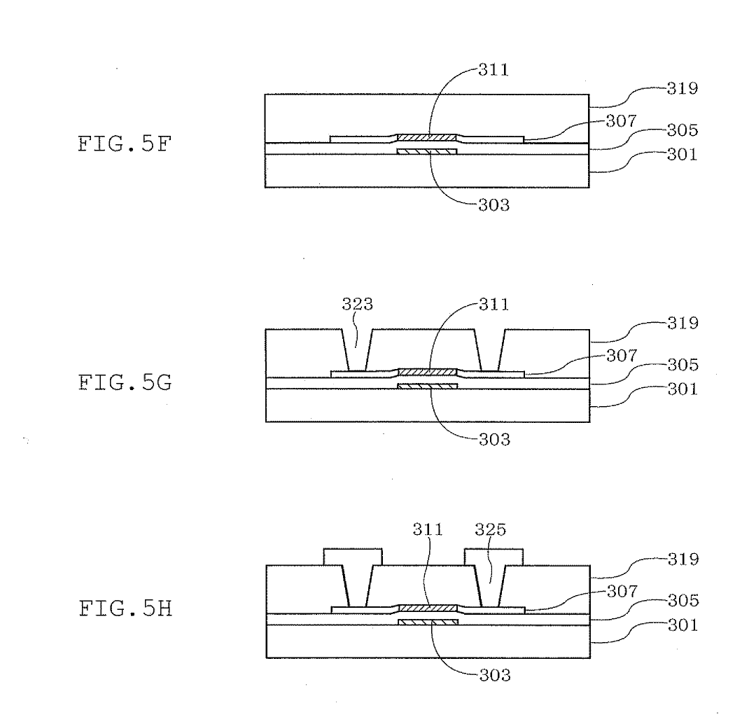

FIGS. 5A to 5H each show a step of the method for producing a transistor of Embodiment 3.

A gate electrode 303 is formed on a substrate 301 (FIG. 5A). Subsequently, a gate insulating film 305, an amorphous oxide film 307 and a buffer film 309 are formed thereon (FIG. 58). On these films, a heat-light conversion film 311 is formed at a position corresponding to the position of the gate electrode 303 (FIG. 5C). Subsequently, an energy ray is irradiated, and the ray is then converted to heat by the heat-light conversion film 311. This heat is transmitted through the buffer film 309, and the amorphous oxide film 307 below the buffer film 309 is allowed to be semiconductive (crystallized) to be a semiconductor film 313. Part of the amorphous oxide film 307 which is not below the heat-light conversion film 311 is allowed to be a source electrode 307a and a drain electrode 307b (FIG. 5D). After the heat-light conversion film 311 and the buffer film 309 are removed (FIG. 5E), a protective film 319 is formed (FIG. 5F). A contact hole 323 is formed in the protective film 319 (FIG. 5G), and a wiring 325 is formed therein (FIG. 5H).

### Embodiment 4

### Bottom-Gate Type Transistor

This embodiment differs from Embodiment 3 in that a buffer film is provided only on a part which is desired to be semiconductive, and an energy ray with a long wavelength and an energy lay with a short wavelength are irradiated so that the amorphous oxide film is crystallized with the energy ray with a long wavelength and the amorphous oxide film has a lowered resistance with the energy ray with a short wavelength.

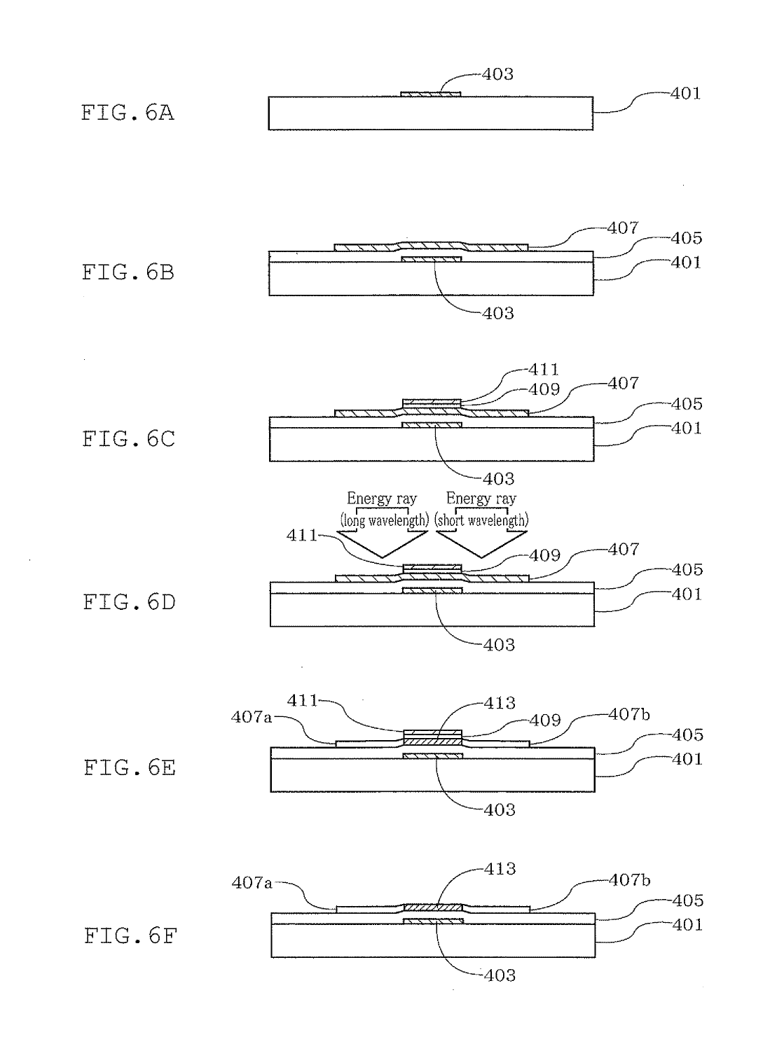

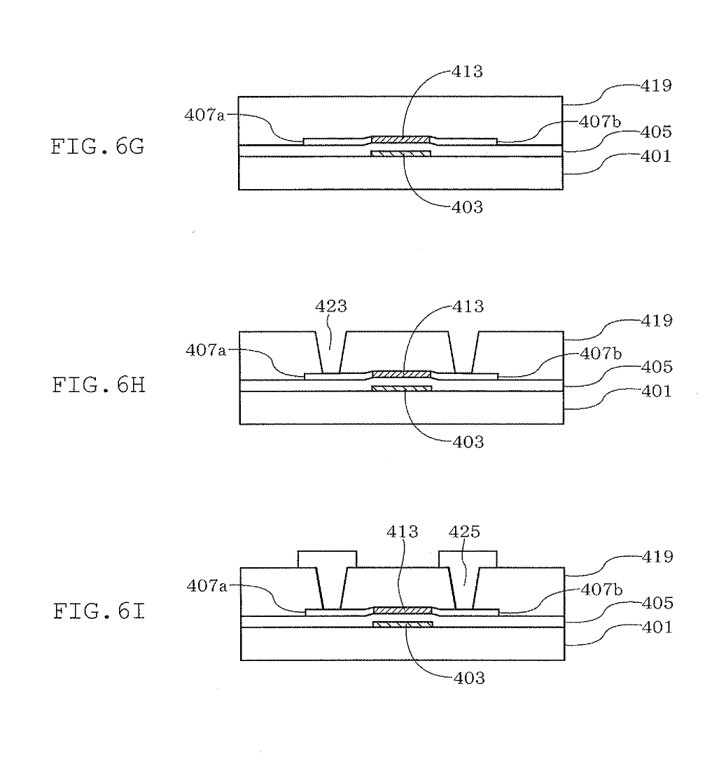

FIGS. 6A to 6I each show a step of the method for producing a transistor of Embodiment 4.

A gate electrode 403 is formed on a substrate 401 (FIG. 6A). Subsequently, a gate insulating film 405 and an amorphous oxide film 407 are formed thereon (FIG. 6B). On these films, a buffer film 409 and a heat-light conversion film 411 are formed at a position corresponding to the position of the gate insulating film 405 (FIG. 6C). An energy ray with a long wavelength and an energy ray with a short wavelength are irradiated (FIG. 6D). The energy ray with a long wavelength is converted to heat by the heat-light conversion film 411. This heat is transmitted through the buffer film 409, the amorphous oxide film 407 below the buffer film 409 is allowed to be semiconductive (crystallized) to be a semiconductor film 413 (FIG. 6E). At the same time, the amorphous oxide films 407 on both the sides are allowed to have a lower resistance with an energy ray with a short wavelength to form a source electrode 407a and a drain electrode 407b, respectively (FIG. 6E). As the energy ray with a long wavelength, an energy ray with a wavelength of about 400 nm to 2400 nm can be used, and as the energy ray with a short wavelength, an energy ray with a wavelength of about 100 nm to 400 nm can be used. After the heat-light conversion film 411 and the buffer film 409 are removed (FIG. 6F), a protective film 419 is formed (FIG. 6G). A contact hole 423 is formed in the protective film 419 (FIG. 6H), and a wiring 425 is formed therein (FIG. 6I).

In this embodiment, since especially the surface of the amorphous oxide film 407 has a lowered resistance, the contact resistance with the wiring 425 is small, and it is expected that the S value or the threshold current are improved when used as a TFT.

In this embodiment, since the resistance of the amorphous oxide film is lowered with an energy ray with a short wavelength, the amorphous oxide film is not necessarily conductive.

In this embodiment, it is preferred that the specific resistance of the amorphous oxide film be 10⁻⁵ to 10⁻¹ Ωcm, particularly preferably 10⁻⁵ to 10⁻² Ωcm. If the specific resistance exceeds 10⁻¹ Ωcm, it is difficult to use the amorphous oxide film as an electrode even though irradiated with light with a short wavelength.

### Embodiment 5

### Bottom-Gate Type Transistor

This embodiment differs from Embodiment 4 in that the heat-light conversion film and the buffer film are not removed after the irradiation of an energy ray.

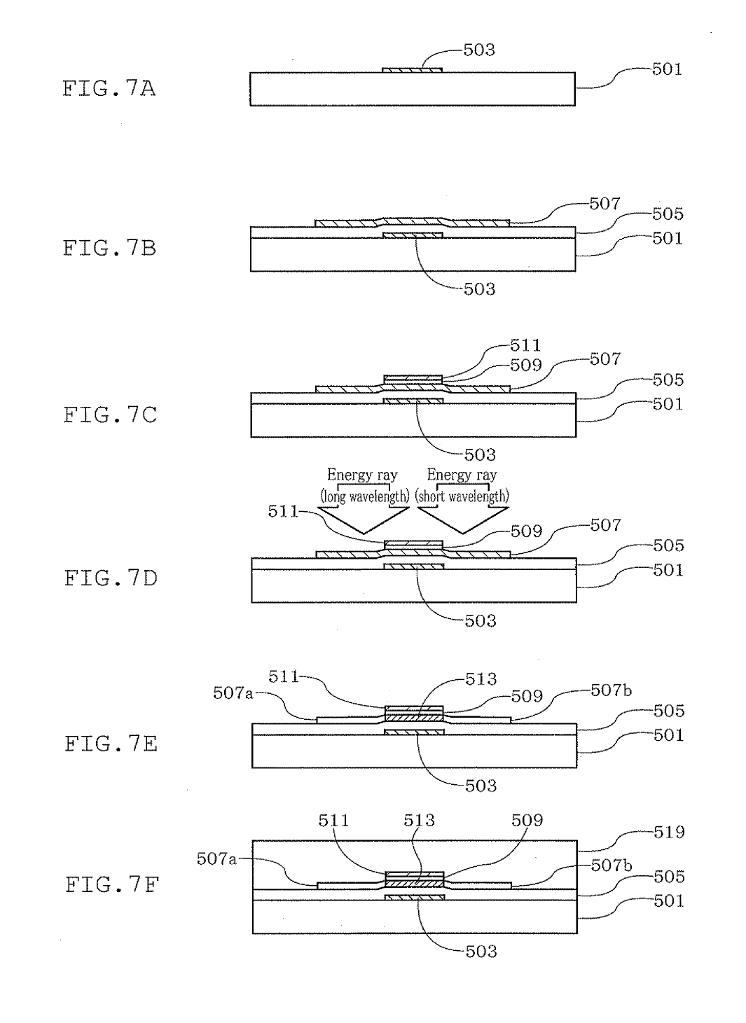

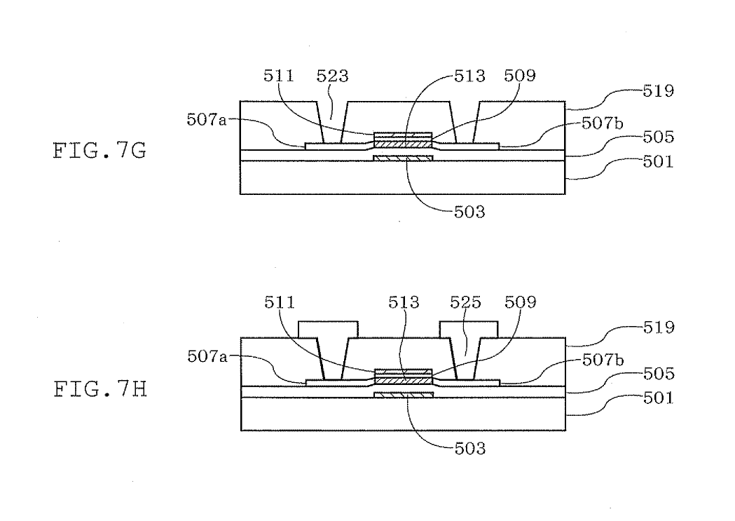

FIGS. 7A to 7H each show a step of the method for producing a transistor of Embodiment 5.

In the same manner as in Embodiment 4, a gate electrode 503 is formed on a substrate 501 (FIG. 7A). A gate insulating film 505 and an amorphous oxide film 507 are formed thereon (FIG. 7B). Subsequently, a buffer film 509 and a heat-light conversion film 511 are formed at a position corresponding to the position of the gate electrode 505 (FIG. 7C). An energy ray with a long wavelength and an energy ray with a short wavelength are irradiated (FIG. 7D). By the energy ray with a long wavelength, the amorphous oxide film 507 below the heat-light conversion film 511 and the buffer film 509 is allowed to be a semiconductor film 513 (FIG. 7E). At the same time, by the energy ray with a short wavelength, the amorphous oxide film 507 which is not covered by the heat-light conversion film 511 and the buffer film 509 is allowed to have a lower resistance to form a source electrode 507a and a drain electrode 507b, respectively (FIG. 7E). A protective film 519 is formed on these films (FIG. 7F). A contact hole 523 is formed in the protective film 519 (FIG. 7G), and a wiring 525 is formed therein (FIG. 7H). The heat-light conversion film 511 remains as a light-shielding layer.

### Embodiment 6

### Bottom-Gate Type Transistor

In this embodiment, a buffer film and a light-heat conversion film are provided, and after heating the light-heat conversion film with an energy ray, the buffer film and the light-heat conversion film are removed together. The crystallized oxide film is irradiated with an energy ray with a short wavelength to form an electrode.

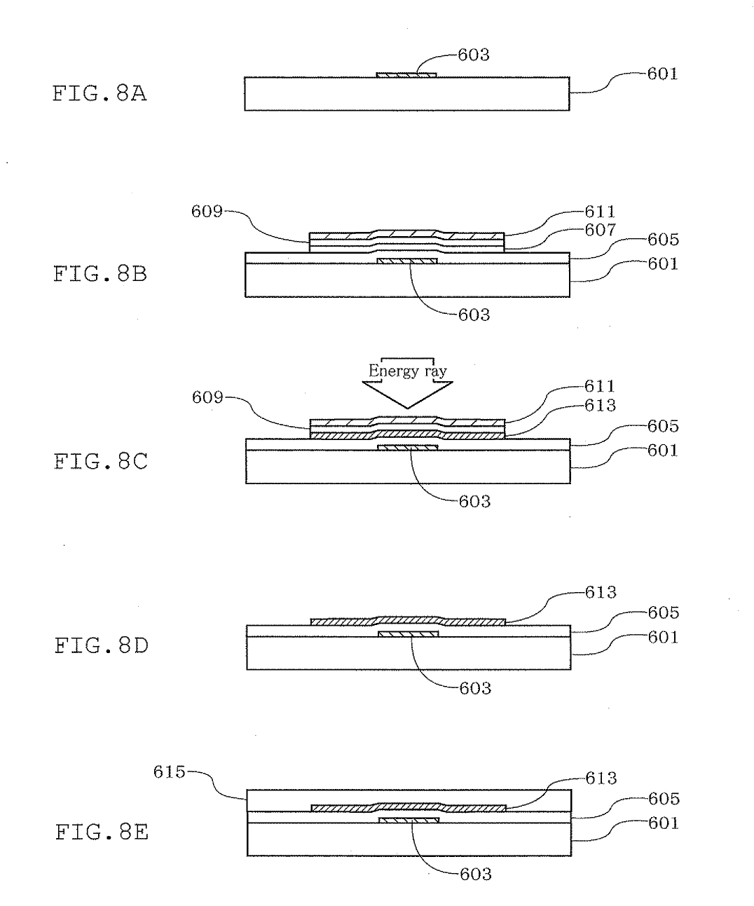

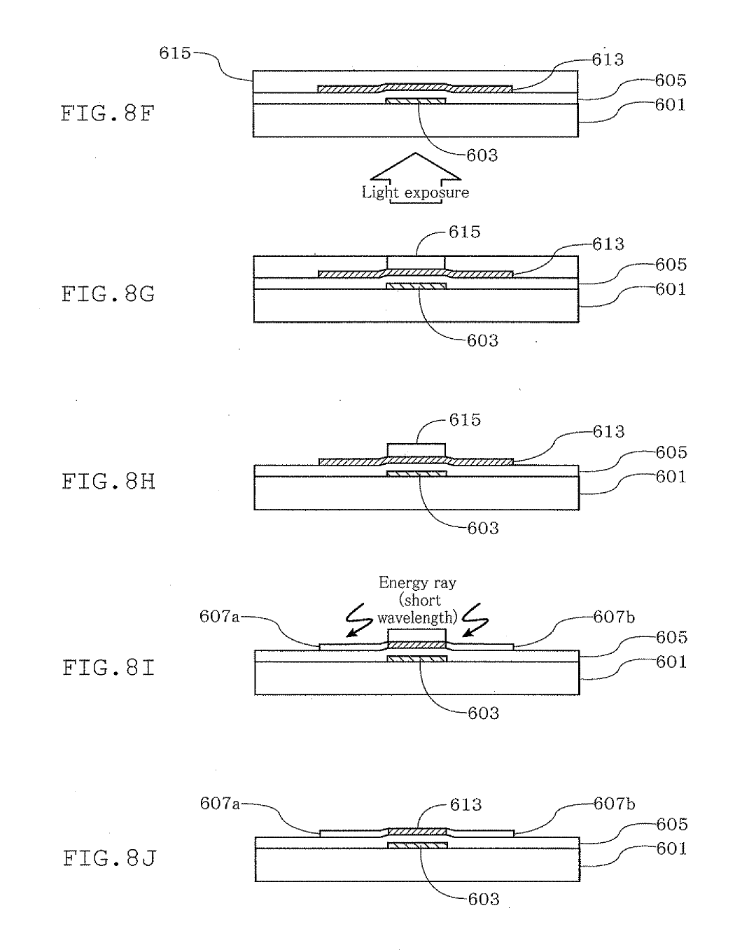

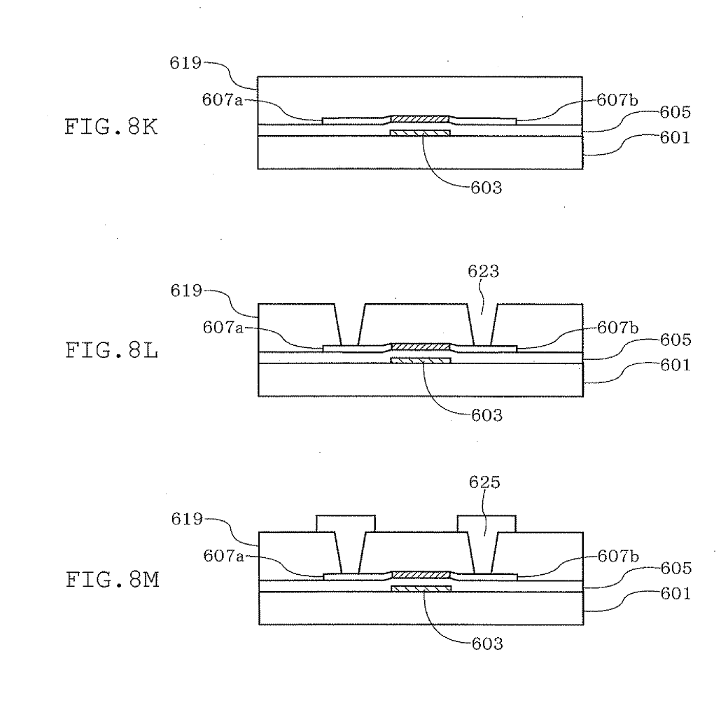

FIGS. 8A to 8M each show a step of the method for producing a transistor of Embodiment 6.

A gate electrode 603 is formed on a substrate 601 (FIG. 8A). Subsequently, a gate insulating film 605, an amorphous oxide film 607, a buffer film 609 and a heat-light conversion film 611 are formed thereon (FIG. 8B). Subsequently, by irradiating an energy ray, the amorphous oxide film 607 is allowed to be semiconductive (crystallized) to form a semiconductor film 613 (FIG. 8C). Subsequently, the buffer film 609 and the heat-light conversion film 611 are removed (FIG. 8D). A resist 615 is applied (FIG. 8E), and light is exposed from below the gate electrode 603 using the gate electrode 603 as a mask (FIG. 8F), whereby the resist 615 is developed and removed (FIGS. 8G and 8H). Under a lower oxygen partial pressure, the semiconductor film 613 which is not covered by the resist 615 is irradiated with an energy ray with a short wavelength to allow it to have a lower resistance to form a source electrode 607a and a drain electrode 607b (FIG. 8I). A resist on the semiconductor film 613 is removed (FIG. 8J). A protective film 619 is formed thereon (FIG. 8K). Further, a contact hole 623 is formed in the protective film 619 (FIG. 8L), and a wiring 625 is provided therein (FIG. 8M).

In this embodiment, since especially the surface of the amorphous oxide film 607 has a lowered resistance, the contact resistance with the wiring 625 is small, and it is expected that the S value or the threshold current are improved when used in a TFT.

In this embodiment, since the amorphous oxide film is allowed to have a lower resistance with an energy ray having a short wavelength, the amorphous oxide film is not necessarily conductive.

In this embodiment, it is preferred that the specific resistance of the amorphous oxide film be 10⁻⁵ to 10⁻¹ Ωcm, particularly preferably 10⁻⁵ to 10⁻² Ωcm. If the specific resistance exceeds 10⁻¹ Ωcm, it may be difficult to use the amorphous oxide film as an electrode even though irradiated with light with a short wavelength.

### Embodiment 7

### Top-Gate Type Transistor

In this embodiment, after heating the light-heat conversion film with an energy ray, the light-heat conversion film is removed.

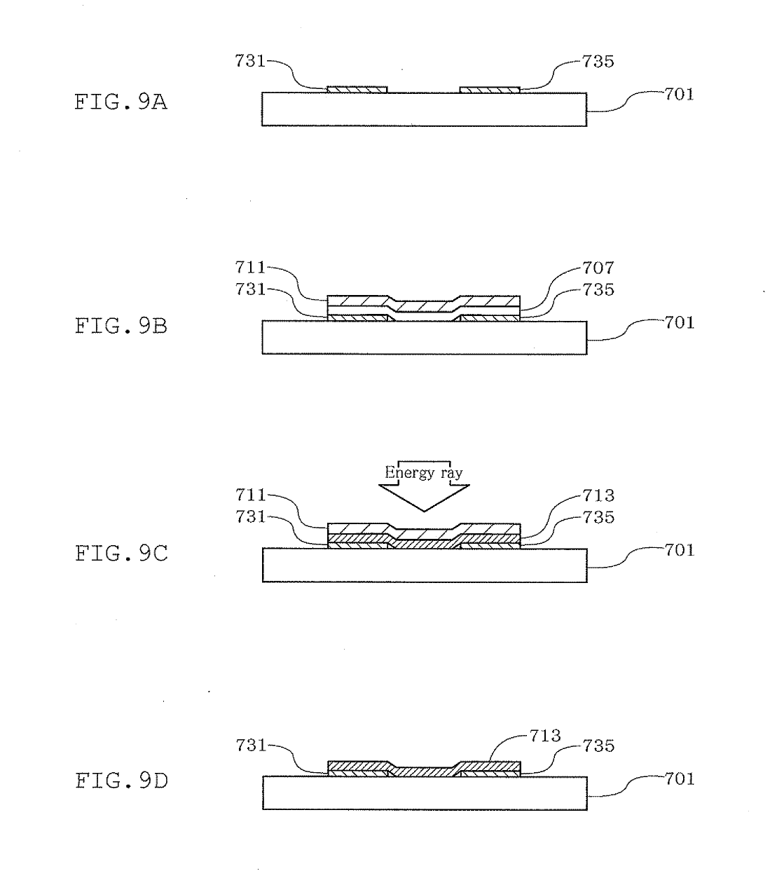

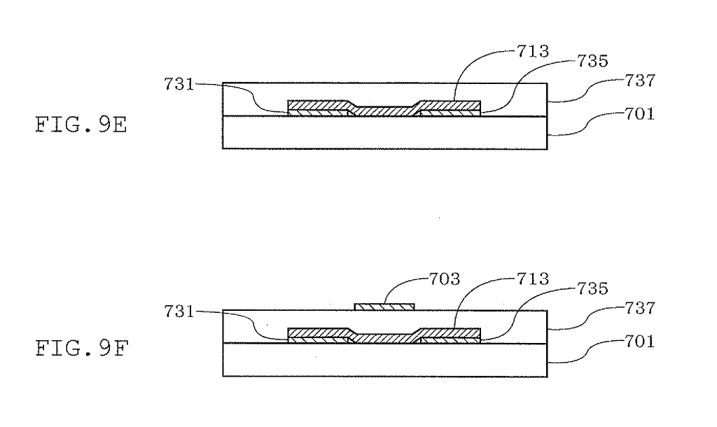

FIGS. 9A to 9F each show a step of the method for producing a transistor of Embodiment 7.

A source electrode 731 and a drain electrode 735 are formed on a substrate 701 (FIG. 9A). Subsequently, an amorphous oxide film 707 and a heat-light conversion film 711 are formed thereon (FIG. 96). Subsequently, by irradiating an energy ray, the amorphous oxide film 707 is allowed to be semiconductive (crystallized) to form a semiconductor film 713 (FIG. 90). Thereafter, the heat-light conversion film 711 is removed (FIG. 9D). Further, an insulating film 737 is formed (FIG. 9E), and a gate electrode 703 is formed on the insulating film 737 (FIG. 9F). The semiconductor film 713 serves as an active layer of a transistor.

### III. Third Aspect

The method for producing a thin film transistor of the invention comprises the steps of forming an amorphous oxide film, forming a heat-receiving film and heating the heat-receiving film.

The above-mentioned amorphous oxide film is subjected to a heat treatment by heating the heat-receiving film. In the thin film transistor of the invention, an amorphous oxide film which has been heat-treated serves as an active layer.

### First Embodiment

The method for producing a thin film transistor of the invention will be explained hereinbelow with reference to the drawings.

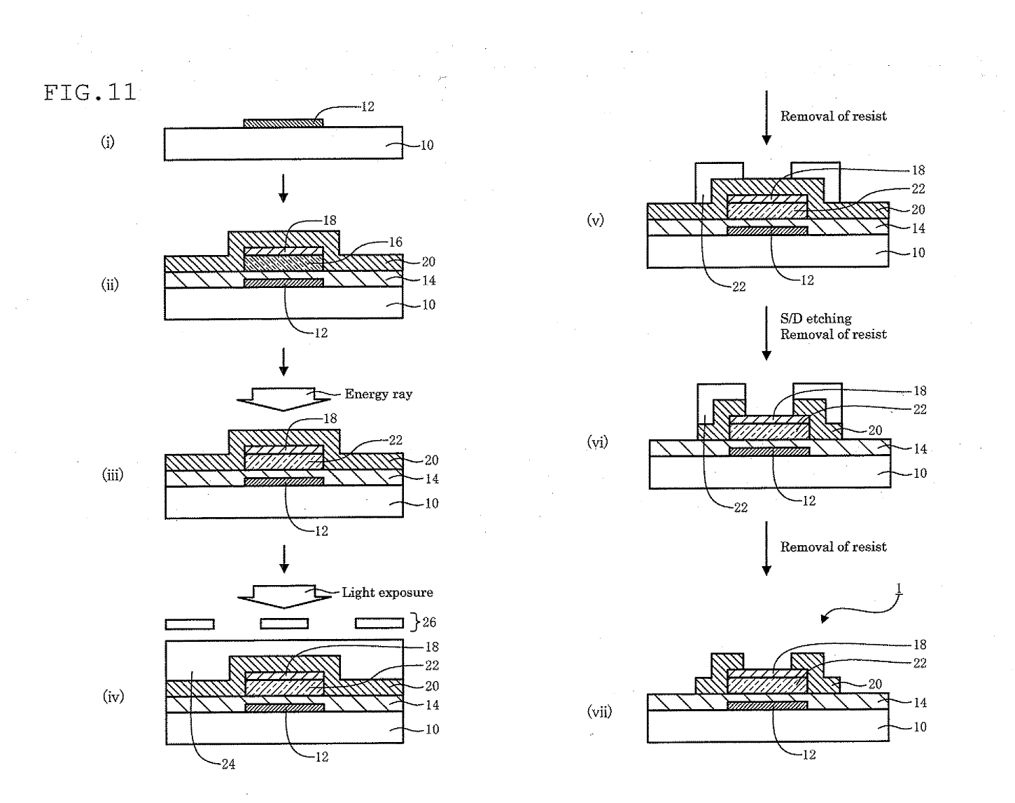

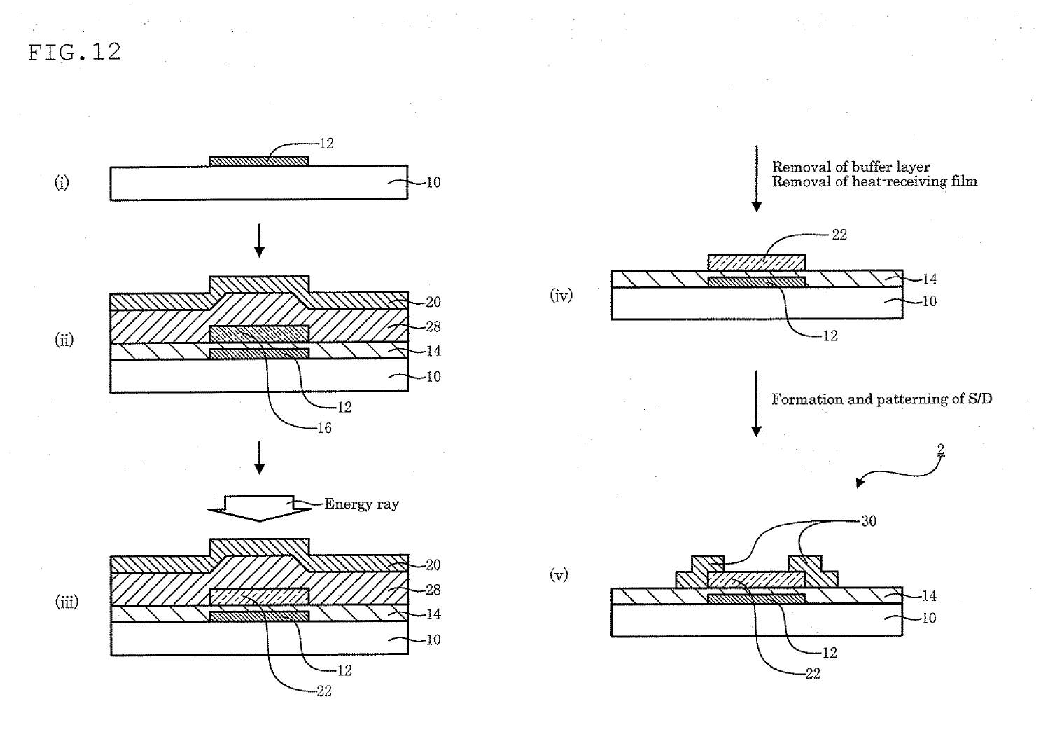

FIG. 11 is a view showing the first embodiment of the method for producing a thin film transistor (bottom-gate type) of the invention.

In the first embodiment, at first, a gate electrode 12 is formed on a supporting substrate 10 (Step (i)). On the supporting substrate 10 provided with the gate electrode 12, a gate insulating film 14 is formed so as to cover the gate electrode 12 and the supporting substrate 10. On the thus formed gate insulating film 14, an amorphous oxide film 16 and a protective film 18 are sequentially formed, and a heat-receiving film 20 is formed so as to cover a stack of the amorphous oxide film 16 and the protective film 18, and the gate insulating film 14 (Step (ii)). The amorphous oxide film 16 can be subjected to a heat treatment by heating the heat-receiving film 20. By the heat treatment, the amorphous oxide film 16 is adjusted to have an appropriate range of resistance value and improved stability, and becomes an amorphous oxide semiconductor film 22 (Step (iii)). Subsequently, a resist 24 is formed so as to cover the heat-receiving film 20. Then, the resultant is exposed to light through an exposure mask 26 (Step (iv)), whereby the resist is formed into a desired shape (Step (v)). Using the resist which has been formed in a desired shape, the heat-receiving film 20 is patterned to form a source electrode and a drain electrode (Step (vi)). Finally, the resist is completely removed to form a thin film transistor 1 (Step (vii)).

In the first embodiment, the thus formed heat-receiving film can be used as a source electrode and/or a drain electrode. Since the heat-receiving layer can be used as an electrode, the steps of producing a thin film transistor can be simplified.

Each step and each member will be explained below in detail.

A gate electrode 12 is formed on the supporting substrate 10 (Step (i)).

There are no particular restrictions on the supporting substrate, and a known substrate can be used as far as it does not impair the advantageous effects of the invention. Specifically, glass substrates such as those formed of non-alkaline glass, soda-lime glass and quartz glass, resin substrates such as those formed of polyethylene terephthalate (PET), polyamide and polycarbonate (PC), or a metal thin film (foil) substrate can be used. A single crystal substrate such as a Si substrate is difficult to be increased in size, and may cause the production cost to be increased.

The thickness of the supporting substrate is normally 0.01 to 10 mm.

There are no particular restrictions on the material for the gate electrode. Known materials can be used as far as they do not impair the advantageous effects of the invention. For example, transparent electrodes such as indium tin oxide (ITO), indium zinc oxide, ZnO and SnO₂, metal electrodes such as Al, Ag, Cr, Ni, Mo, Au, Ti, Ta, Cu, W and Nb, or metal electrodes of alloys containing these metals can be used.

The gate electrode may have a stack structure of two or more of the above-mentioned electrodes. It is preferable to allow the gate electrode to be a stack, since contact resistance can be decreased and interfacial strength can be increased.

This gate electrode can be formed by sputtering, and the thickness thereof is normally 50 to 300 nm.

On the supporting substrate 10 which is provided with the gate electrode 12, the gate insulating film 14 is formed so as to cover the gate electrode 12 and the supporting substrate 10. On the thus formed gate insulating film 14, the amorphous oxide film 16 and the protective film 18 are sequentially formed, and the heat-receiving film 20 is formed so as to cover a stack of the amorphous oxide film 16 and the protective film 18, and the gate insulating film 14 (Step (iii)).

There are no particular restrictions on the gate insulating film used, and known gate insulating films can be used as far as they do not impair the advantageous effects of the invention. As for the material for forming the gate insulating film, for example, compounds such as SiO₂, SiNx (it may contain hydrogen), Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these, SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable.

Meanwhile, the oxygen number of these compounds may not necessarily coincide with the stoichiometrical ratio (for example, they may be SiO₂ or SiOx).

The gate insulating film may be a stack structure in which two or more insulating films differing in material are stacked. The gate insulating film may be crystalline, polycrystalline or amorphous. It is preferred that the gate insulating film be polycrystalline or amorphous in respect of productivity.

The thickness of the gate insulating film is normally 5 to 500 nm.

The amorphous oxide film is preferably an amorphous oxide film containing one or more elements selected from the group consisting of In, Zn and Sn. More preferably, it is an amorphous oxide film containing two or more elements selected from the group consisting of In, Zn and Sn. Further preferably, the amorphous oxide film containing two or more elements selected from the group consisting of In, Zn and Sn is an amorphous oxide film containing In and Zn or an amorphous oxide film containing Zn and Sn.

If the amorphous oxide film contains in and Zn, it is preferred that this amorphous oxide film further contain an element X other than In and Zn. The element X is preferably an element selected from the group consisting of Ga, Ar, Zr, a lanthanoid (for example, La, Ce, Pr, Nd, Sm, Eu, Gd, Tb, Dy, Ho, Er, Tm, Yb and Lu).

In the amorphous oxide film containing In, Zn and the element X, it is preferred that the atomic ratio of In, Zn and the element X satisfy the following formulas (1) to (3):

In/(In+Zn+X)=0.25 to 0.75 (1)

Zn/(Zn+X)=0.1 to 0.99 (2)

In/(In+X)=0.25 to 0.99 (3)

In the above formula (1), if the in/(In+Zn+X) is less than 0.25, the mobility may be lowered, the S value may be increased, the moisture proof may lowered and the resistance to chemicals such as an acid and an alkali may be lowered. On the other hand, if In/(In+Zn+X) exceeds 0.75, the off current and the gate leakage current may be increased, the S value may be increased and the plasma resistance may be lowered. In addition, the threshold value may be negative to cause the TFT to be normally-on. The In/(In+Zn+X) is more preferably 0.35 to 0.65.

In the above formula (2), if the Zn/(Zn+X) is less than 0.1, the mobility may be lowered and the S value may be increased. Further, a heat treatment at a high temperature for a long time may be required to stabilize the amorphous oxide film and the wet etching speed may be slow. On the other hand, if the Zn/(Zn+X) exceeds 0.99, the mobility may be lowered, the S value may be increased, the stability and resistance to heat may be lowered, the moisture proof may be lowered, the resistance to chemicals such as an acid and an alkali may be lowered, and an increase in shift of threshold voltage may occur. The Zn/(Zn+X) is more preferably 0.35 to 0.95, with 0.51 to 0.9 being particularly preferable.

In the above formula (3), if the In/(In+X) is less than 0.25, the mobility may be lowered, the S value may be increased and the resistance to chemicals such as an acid and an alkali may be lowered. On the other hand, if the In/(In+X) exceeds 0.99, the off current and the gate leakage current may be increased, the S value may be increased and the plasma resistance may be lowered. In addition, the threshold value may be negative to cause the TFT to be normally-on. The In/(In+X) is more preferably 0.51 to 0.97, with 0.58 to 0.95 being particularly preferable.

It is preferred that the specific resistance of the amorphous oxide film be 10⁻⁴ to 10¹⁰ Ωcm. If the specific resistance of the amorphous oxide film is less than 10⁻⁴ Ωcm, the amorphous oxide film may remain as a conductive film even if it is subjected to a heat treatment. On the other hand, if the specific resistance of the amorphous oxide film exceeds 10¹⁰ Ωcm, the amorphous oxide film may be an insulating film after a heat treatment.

The film thickness of the amorphous oxide film is normally 0.5 to 500 nm, preferably 1 to 150 nm, more preferably 3 to 80 nm, and particularly preferably 10 to 60 nm. If the film thickness of the amorphous oxide film is less than 0.5 nm, it may be difficult to attain uniform film formation on the industrial scale. On the other hand, if the thickness of the amorphous oxide film exceeds 500 nm, the film formation time may be too long to be conduced on the industrial scale. If the film thickness of the amorphous oxide film is within a range of 3 to 80 nm, TFT properties such as the mobility and the on-off ratio can be improved.

There are no particular restrictions on the method for forming the amorphous oxide film. For example, chemical film formation methods, physical film formation methods or the like can be used. Specifically, DC sputtering, AC sputtering or RF sputtering may be used. It is preferable to use DC sputtering or AC sputtering. As compared with RF sputtering, DC sputtering and AC sputtering can suppress damage during the film formation. Further, when a film obtained by these film formation methods is used in a field effect transistor, advantageous effects such as a decrease in shift of a threshold voltage, an increase in mobility, a decrease in threshold voltage and a decrease in S value can be expected.

The amorphous nature of the oxide film can be judged by the absence of a specific peak in an X-ray diffraction or by the presence of a hallow pattern in an X-ray diffraction. In the invention, when a clear peak cannot be found in an X-ray diffraction, the amorphous oxide film may contain fine crystals which can be observed by a transmission electron microscope (TEM). The average particle size of these fine crystals is preferably 10 nm or less, more preferably 5 nm or less and particularly preferably 1 nm or less. If the amorphous oxide film contains fine crystals, the mobility can be improved. However, if the amorphous oxide film contains fine crystals with an average particle size exceeding 10 nm, a variation among devices may be large when this amorphous oxide film is used in a transistor.

There are no particular restrictions on the protective film to be used. Known protective films may be used as far as they do not impair the advantageous effects of the invention. The same materials as those for the above-mentioned gate insulating film may be used.

The protective film may be a stack structure in which two or more protective films differing in material are stacked. The protective film may be crystalline, polycrystalline or amorphous. It is preferred that the protective film be a polycrystalline or amorphous in respect of productivity.

The thickness of the protective film is normally 5 to 500 nm.

As the material for the light-receiving film, there cyan be used wiring materials such as Mo and Mo alloys (Mo—W, Mo—Ta or the like), Cu and Cu alloys (Cu—Mn, Cu—Mo, Cu—Mg), Al and Al alloys (Al—Nd, Al—Ce, Al—Zr or the like), Ag and Ag alloys, Cr and Cr alloys, and Ta and Ta alloys, a metal having a high melting point such as Ti, V, Nb and Hf and alloys thereof, diamond-like carbon (DLC), oxides, nitrides, carbides and oxynitrides of these metals or the like.

Of the above-mentioned materials for the heat-receiving film, wiring materials such as Mo and a Mo alloy (Mo—W, Mo—Ta or the like), Cu and a Cu alloy (Cu—Mn, Cu—Mo or Cu—Mg), Al and an Al alloy (Al—Nd, Al—Ce, Al—Zr or the like), Ag and an Ag alloy, Cr and an Cr alloy and Ta and a Ta alloy, a metal having a high melting point such as Ti, V, Nb and Hf and an alloy of these metals are preferable. The wiring materials, the high-melting-point metals and alloys of these metals as mentioned above have a high light transmission and have a high coefficient of thermal conductivity, and hence, they can allow the heat-receiving film to be heated uniformly.

The specific resistance of the heat-receiving film is preferably 1×10⁻³ Ωcm or less, more preferably 5×10⁻⁴ Ωcm or less, and particularly preferably 1×10⁻⁴ Ωcm or less. If the specific resistance of the heat-receiving film exceeds 1×10⁻³ Ωcm, it is difficult to use the heat-receiving film which has been patterned can be used as the electrode.

There are no particular restrictions on the method for forming the heat-receiving film. For example, chemical film formation methods, physical film formation methods or the like can be used. Specifically, DC sputtering, AC sputtering or RF sputtering may be used. It is preferable to use DC sputtering or AC sputtering.

The thickness of the heat-receiving film is normally 5 to 500 nm.

By heating the heat-receiving film 20, the amorphous oxide film 16 can be subjected to a heat treatment. By a heat treatment, it is possible to adjust the resistance of the amorphous oxide film 16 in an appropriate value range, as well as to improve the stability thereof. As a result, an amorphous oxide semiconductor film 22 is formed (Step (iii)).

As the method for heating the heat-receiving film, it is preferable to use lamp heating, ultraviolet lamp heating, semiconductor laser heating, excimer laser heating, an electromagnetic induction heating and plasma jet heating.

Of these heating methods, if uniform heating of a large area is intended, infrared lamp heating, visible lamp heating or semiconductor laser heating are more preferable. If heating is intended to be completed for a short period of time, semiconductor laser heating, excimer laser heating, electromagnetic induction heating or plasma jet heating are more preferable.

In addition to the above-mentioned heating methods, a method for producing a semiconductor thin film disclosed in JP-A-2004-134577 or the like can be used.

The amorphous oxide film has a high transmission to an energy ray. Therefore, it is difficult to subject it to a heat treatment directly by the above-mentioned method. However, by heating the heat-receiving film which can be heated more easily as compared with the amorphous oxide film, a heat treatment of the amorphous oxide film can be conducted efficiently.

In FIG. 11, an energy ray is irradiated toward the heat-receiving film 20 of the stack. The direction of irradiating an energy ray is not limited to that shown in FIG. 11. An energy ray may be irradiated toward the supporting substrate 10 of the stack.

If heating is conducted by irradiating the heating-receiving film with light (an energy ray) from a lamp (infrared lamp, visible lamp, ultraviolet lamp), or light from a semiconductor, light from an excimer laser ray as shown in the Step (iii) of FIG. 11, it is preferred that the light used in the irradiation have a wavelength in the UV region, the visible region or the infrared region. Light with a wavelength range of 100 nm to 2400 nm is more preferable.

There are no particular restrictions on a lamp used in lamp heating. For example, a halogen lamp, a metal halide lamp, a xenon arc lamp, a carbon arc lamp, a high-pressure sodium lamp, a low-pressure mercury lamp, a high-pressure mercury lamp or the like may be used. Lamp heating can be conducted by using one or two or more of these lamps.

If a semiconductor laser heating or an excimer laser heating is used in heating the heat-receiving film, as for the oscillation method thereof, it is possible to use beam from a continuous oscillation type laser (CW laser beam) or beam from a pulse oscillation type laser (pulse laser beam). Specific examples of a laser beam which can be used in the invention include a gas laser such as an Ar laser, a Kr laser and an excimer laser; a laser of a medium obtained by adding one or more elements selected from Nd, Yb, Cr, Ti, Ho, Er, Tm and Ta as a dopant to monocrystalline YAG (yttrium aluminum garnet), a polycrystalline ceramic YAG, YVO₄, forsterite (Mg₂SiO₄), YAlO₃, GdVO₄, Y₂O₃, YVO₄, YAlO₃ or GdVO₄; a glass laser, a ruby laser, an alexandrite laser, a Ti:sapphire laser, a copper vapor laser and a gold vapor laser.

By irradiating fundamental waves of a laser beam or the second to fourth harmonic wave of these fundamental waves, it is possible to improve crystalline properties of the amorphous oxide semiconductor film. It is preferable to use laser light having energy larger than the band gap of the oxide semiconductor film. For example, laser light emitted from an excimer laser oscillator such as KrF, ArF, XeCl or XeF is used.

If the heat-receiving film is heated by a semiconductor laser, as the semiconductor laser apparatus for generating a semiconductor laser beam, it is preferable to use a continuous oscillation semiconductor laser apparatus having an oscillation wavelength of about 350 to 1000 nm.

A pulse laser such as an excimer laser may cause an uneven display since energy varies greatly for each pulse. Normally, the pulse variation of an excimer laser is 5% to 10% on the peak-to-peak basis. In the case of a semiconductor-excited YAG laser which is relatively stable, it undergoes a 2% to 3% peak-to-peak pulse variation. On the other hand, a variation in outputs of the above-mentioned continuous oscillation semiconductor laser apparatus can be suppressed to 0.5% or less on the peak-to-peak basis. Therefore, when a TFT having the heat-receiving film which is heated by a continuous oscillation semiconductor laser apparatus is used in an organic EL display or the like, it is possible to suppress unevenness in display.

An active layer of the above-mentioned semiconductor laser apparatus may be a compound semiconductor such as GaN, InGaN, GaAs, AlGaAs, InGaAs, InGaAsP, InGaAlP, ZnSe, ZnS and ZiC. In respect of high output, long life and low cost, it is preferable to use a semiconductor laser apparatus which uses GaAs or AlGaAs as an active layer.

By subjecting the amorphous oxide film to a heat treatment, the amorphous oxide film is allowed to be an amorphous oxide semiconductor film. Here, it is preferred that the heat treatment temperature of the amorphous oxide film be equal to or higher than the film forming temperature of the amorphous oxide film and equal to or lower than the crystallization temperature of the amorphous oxide film.

There are no particular restrictions on the heat treatment temperature of the amorphous oxide film during the heating of the heat-receiving film insofar as it is a temperature range which does not cause the crystallization of the amorphous oxide film. The heat treatment temperature is, however, preferably 200 to 600° C. Specifically, it is preferable to conduct a heat treatment at 230 to 550° C. (preferably 250 to 500° C., more preferably 300 to 480° C., further preferably 350 to 470° C.) for 0.1 to 240 minutes. The heat treatment is conducted preferably for 0.5 to 120 minutes, further preferably 1 to 30 minutes. If the heat treatment temperature is less than 200° C., the heat treatment time may be prolonged significantly. On the other hand, if the heat treatment temperature exceeds 600° C., the amorphous film may be partially crystallized to cause the film quality to be uneven or the like.

When heating the heat-receiving film, a reflection suppressing film such as an SiO₂ film and an SiNx film may be further provided on the heat-receiving film. Due to the provision of a reflection suppressing film, heating efficiency can be improved. The refractive index of the reflection suppressing film is preferably about 1.5 to 2.5.

The electron carrier concentration of the amorphous oxide semiconductor film obtained by the heat treatment is preferably 10¹³ to 10¹⁸/cm³. If the electron carrier concentration of the amorphous oxide semiconductor film is less than 10¹³/cm³, the resulting transistor may have a small mobility. On the other hand, if the electron carrier concentration of the amorphous oxide semiconductor film exceeds 10¹⁸/cm³, the resulting transistor may have a high off current.

The specific resistance of the amorphous oxide semiconductor film is preferably 10⁻² to 10⁸ Ωcm, more preferably 10⁻¹ to 10⁶ Ωcm, and further preferably 10⁰ to 10⁴ Ωcm. If the specific resistance of the amorphous oxide semiconductor film is less than 10⁻¹ Ωcm, the off current of a transistor may be increased. On the other hand, if the specific resistance of the amorphous oxide semiconductor film exceeds 10⁸ Ωcm, a transistor may have a small mobility.

The band gap of the amorphous oxide semiconductor film is preferably 2.0 to 6.0 eV, more preferably 2.8 to 4.8 eV. If the band gap of the amorphous oxide semiconductor film is less than 2.0 eV, the amorphous oxide semiconductor film may absorb visible rays to cause a field effect transistor to malfunction. On the other hand, if the band gap of the amorphous oxide semiconductor film exceeds 6.0 eV, a field effect transistor may not function.

It is preferred that the amorphous oxide semiconductor film be a nondegenerate semiconductor which shows thermal activity. If the semiconductor film is a degenerate semiconductor, the off current/gate leakage current may be increased due to an excessive amount of carriers, or the threshold value becomes negative to cause a transistor to be normally-on.

The surface roughness (RMS) of the amorphous oxide semiconductor film is preferably 1 nm or less, more preferably 0.6 nm or less, with 0.3 nm or less being particularly preferable. If the surface roughness of the amorphous oxide semiconductor film exceeds 1 nm, the mobility of a transistor may be lowered.

The energy width (E₀) on the non-localized level of the amorphous oxide semiconductor film is preferably 14 meV or less, more preferably 10 meV or less, further preferably 8 meV or less, and particularly preferably 6 meV or less. If the energy width (E₀) on the non-localized level of the amorphous oxide semiconductor film exceeds 14 may, the mobility of a transistor may be lowered or the threshold value and the S value may be too large. A large energy width (E₀) on the non-localized level of the amorphous oxide semiconductor film appears to be caused by a poor short range order of the amorphous film.

The energy width (E₀) on the non-localized level of the amorphous oxide semiconductor film can be obtained, while changing the temperature in a range from 4 to 300K, from the relationship between the activation energy and the carrier concentration measured by using Hall effects.

A resist 24 is formed so as to cover the heat-receiving film 20. Thereafter, the resultant is exposed to light through an exposure mask 26 (Step (iv)) to allow the resist to have a desired shape (Step (v)). Using the resist formed into a desired shape, the heat-receiving film 20 is patterned to form a source electrode and a drain electrode (Step (vi)).

In the invention, preferably, the heat-receiving film 20 is patterned to form at least one of a source electrode, a drain electrode and a gate electrode. The method for patterning the heat-receiving film is not particularly restricted, and known patterning methods such as dry etching, wet etching and lift off can be used.

Finally, the resist is completely removed to form a thin film transistor 1 (Step (vii)).

The thin film transistor 1 is a field effect transistor provided with a semiconductor layer, a substrate, a source electrode, a drain electrode, a gate electrode and a gate insulting film.

The ratio (W/L) of the channel width W and the channel length L of the thin film transistor is normally 0.1 to 100, preferably 1 to 20 and particularly preferably 2 to 8. If the W/L is less than 0.1, the field effect mobility of the thin film transistor may be lowered and the pinch off may be unclear. If the W/L exceeds 100, the thin film transistor may suffer a large amount of current leakage and may have a lowered on-off ratio.

The channel length L of the thin film transistor is normally 0.1 to 1000 μm, preferably 1 to 100 μm, and further preferably 2 to 10 μm. If the channel length L of the thin film transistor is less than 0.1 μm, it may be difficult to produce the thin film transistor on the industrial scale, and the current leakage may be increased. If the channel length L exceeds 1000 μm, the device may become too large in size.

The mobility of the thin film transistor is preferably 1 cm²/Vs or more, more preferably 3 cm²/Vs or more, and particularly preferably 8 cm²/Vs or more. If the mobility of the thin film transistor is less than 1 cm²/Vs, the switching speed may become slow.

The on-off ratio of the thin film transistor is preferably 10⁶ or more, more preferably 10⁷ or more, and particularly preferably 10⁸ or more.

The off current of the thin film transistor is preferably 2 pA or less, more preferably 1 pA or less. If the off current exceeds 2 pA, when the thin film transistor is used in a display, the display may have a poor contrast or poor uniformity.

It is preferred that the thin film transistor have a gate leakage current of 1 pA or less. If the gate leakage current exceeds 1 pA, when the thin film transistor is used in a display, the display may have a poor contrast.

The threshold voltage of the thin film transistor is preferably 0 to 4 V, more preferably 0 to 3 V, and particularly preferably 0 to 2 V. If the threshold voltage is smaller than 0 V, the thin film transistor becomes normally-on, and a voltage is required to be applied when the transistor is in the off state, which may increase the consumption power of the thin film transistor. If the threshold voltage exceeds 4 V, the driving voltage may be increased, resulting in an increase in the consumption power of the thin film transistor.

The S value of the thin film transistor is preferably 0.8 V/dec or less, more preferably 0.5 V/dec or less, further preferably 0.3 V/dec or less, and particularly preferably 0.2 V/dec or less. If the S value is larger than 0.8 V/dec, the driving voltage may be too large to increase the consumption power of the thin film transistor.

The S value (Swing Factor) is a value indicating the sharpness of rising of the drain current from the off-state to the on-state when the gate voltage of a transistor is increased from the off-state. Specifically, the S value is defined by the following formula. As shown by the following formula, the S value is an increase in gate voltage when the drain current increases by one digit (10 times).

S value=dVg/dlog(Ids)

When the S value is high (for example, exceeding 0.8 V/dec), it is required to apply a high gate voltage when switching from the on-state to the off-state, which may result in an increased consumption power.

Since the thin film transistor of the invention has a low S value, the rising of the drain current is sharp (“Thin Film Transistor Technology”, by Ukai Yasuhiro, 2007, published by Kogyo Chosakai Publishing, Inc.). Therefore, when used in an organic EL display driven by DC current, the consumption power can be significantly decreased.

In the thin film transistor of the invention, a shift in threshold voltage before and after the application of a 3 μA-DC current at 60° C. for 100 hours is preferably 1.0 V or less, more preferably 0.5 V or less. When the shift amount exceeds 1 V, if a transistor having such a shift amount is used in an organic EL display, the image quality thereof may be changed.

In addition, in the thin film transistor of the invention, it is preferred that hysteresis when the gate voltage is increased and decreased in a transmission curve and a variation in threshold voltage when measured in the air (change in surrounding atmosphere) be small.

### Second Embodiment

FIG. 12 is a view showing steps of the method for producing a thin film transistor (bottom-gate type) of the second embodiment of the invention.

In the second embodiment, at first, the gate electrode 12 is formed on a supporting substrate 10 (Step (i)). On the supporting substrate 10 provided with the gate electrode 12, the gate insulating film 14 is formed so as to cover the gate electrode 12 and the supporting substrate 10. On the thus formed gate insulating film 14, the amorphous oxide film 16 and a buffer layer 28 are sequentially formed, and the heat-receiving film 20 is formed on the buffer layer 28 (Step (ii)). By heating the heat-receiving film 20, the amorphous oxide film 16 is heat-treated, whereby the amorphous oxide film 16 is allowed to be an amorphous oxide semiconductor film 22 (Step (iii)). The heat-receiving film 20 and the buffer layer 28 are removed (Step (iv)). Finally, a source electrode 30 and a drain electrode 30 are formed, followed by patterning to form a thin film transistor 2 (Step (v)).

As in the second embodiment, it is preferred that the method for producing a thin film transistor of the invention comprise the step of stacking a buffer layer and the step of removing the heat-receiving film and the buffer layer.

The buffer layer serves as a structural body which keeps a spatial distance in the film thickness direction constant. Due to the provision of the buffer layer, the amorphous oxide film hardly changes in volume, thereby to allow the amorphous oxide semiconductor film obtained after the heat treatment to be uniform.

As the material for the buffer layer, compounds such as

SiO₂, SiNx, Al₂O₃, Ta₂O₅; TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like can be used. Of these, SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable. The oxygen number of these compounds may not necessarily coincide with the stoichiometrical ratio (for example, they may be SiO₂ or SiOx).

In addition to the above-mentioned inorganic compounds, organic compounds may be used insofar as they have heat resistance.

Of the above-mentioned compounds, oxides are particularly preferable as the material for the buffer layer. If oxides are used, it is possible to prevent oxygen from entering the buffer layer when the heat-receiving film is heated.

Such a buffer layer may be a stack structure in which two or more buffer layers differing in material are stacked. The buffer layer may be crystalline, polycrystalline or amorphous. It is preferred that the buffer layer be polycrystalline or amorphous in respect of the production on the industrial scale.

The thickness of the buffer layer is preferably 5 to 500 nm, more preferably 10 to 300 nm, and particularly preferably 20 to 200 nm.

The features such as each member other than the buffer layer in the second embodiment are similar to those in the first embodiment.

### Third Embodiment

The method for producing a thin film transistor of the invention can be applied to both a bottom-gate type transistor and a top-gate type transistor.

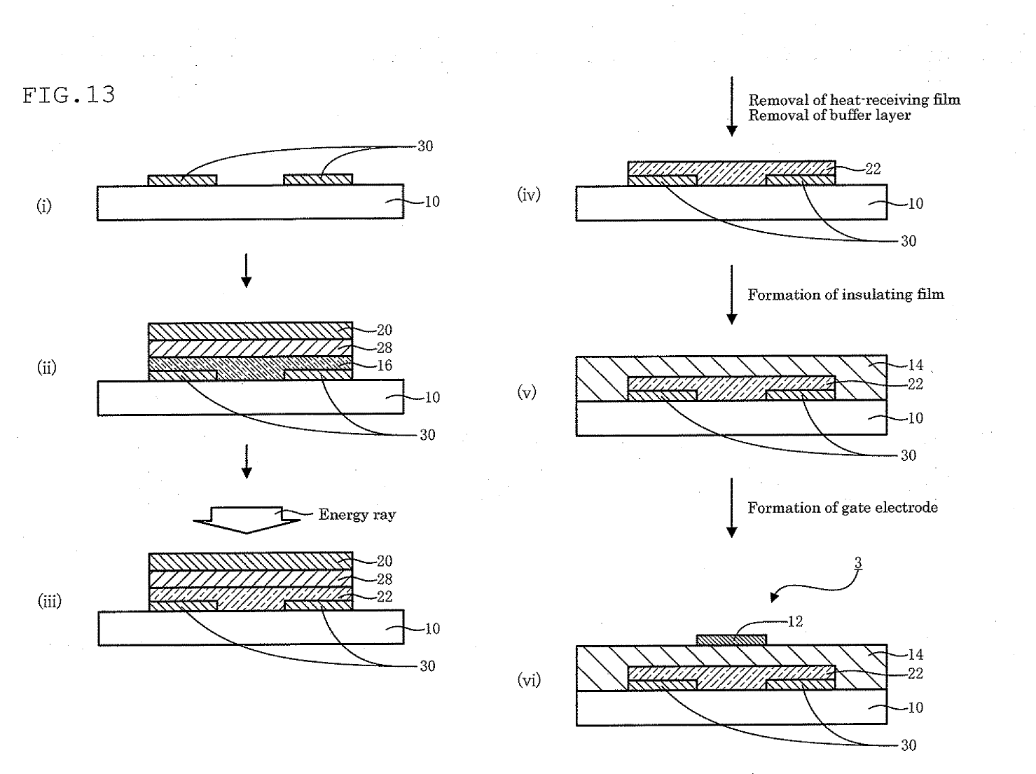

FIG. 13 is a view showing steps of the third embodiment of the method for producing a thin film transistor (top-gate type) of the invention.

In the third embodiment, at first, the source electrode 30 and the drain electrode 30 are formed on the supporting substrate 10 (Step (i)). On the supporting substrate 10 provided with the source electrode 30 and the drain electrode 30, the amorphous oxide film 16, the buffer layer 28 and the heat-receiving film 20 are sequentially formed (Step (ii)). By heating the heat-receiving film 20, the amorphous oxide film 16 is heat-treated, whereby the amorphous oxide film 16 is allowed to be the amorphous oxide semiconductor film 22 (Step (iii)). The buffer layer 28 and the heat-receiving film 20 are removed (Step (iv)). The gate insulting film 14 is formed so as to cover the source electrode 30, the drain electrode 30 and the amorphous oxide semiconductor film 22 on the supporting substrate 10 (Step (v)). Finally, the gate electrode 12 is formed on the gate insulating film 14 to form a thin film transistor 3 (Step (vi)).

The features such as each member in the third embodiment are similar to those in the first and second embodiments.

### Fourth Embodiment

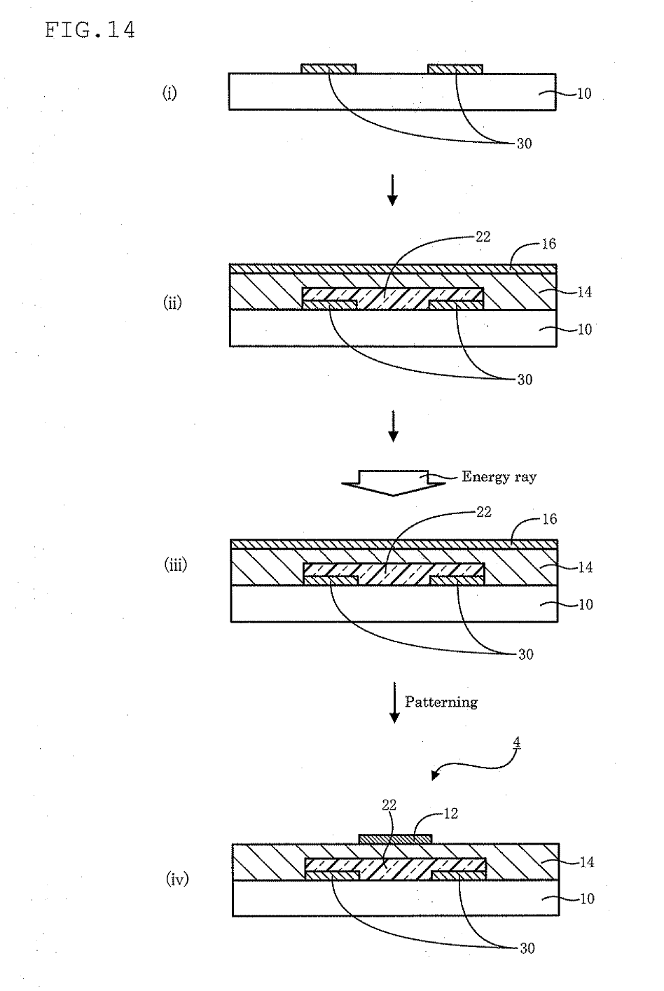

FIG. 14 is a view showing the third embodiment of the method for producing a thin film transistor (top-gate type) of the invention.

In the fourth embodiment, at first, the source electrode 30 and the drain electrode 30 are formed on the supporting substrate 10 (Step (i)). On the supporting substrate 10 provided with the source electrode 30 and the drain electrode 30, the amorphous oxide semiconductor film 22 is stacked. Then, the gate insulating film 14 is formed so as to cover the source electrode 30, the drain electrode 30 and the oxide semiconductor film 22. Further, the heat-receiving film 16 is formed on the gate insulating film 14 (Step (ii)). After heating the heat-receiving film 16 of the stack thus obtained, patterning is conducted to form the gate electrode 12, whereby a thin film transistor 4 is formed (Step (iii) and Step (iv)).

The features such as each member in the fourth embodiment are similar to those in the first to third embodiments.

In the third embodiment, the gate electrode is farmed separately. However, as in the fourth embodiment, the gate electrode can be formed by heating and patterning the heat-receiving film. By forming the gate electrode from the heat-receiving film in this way, the entire process can be simplified.

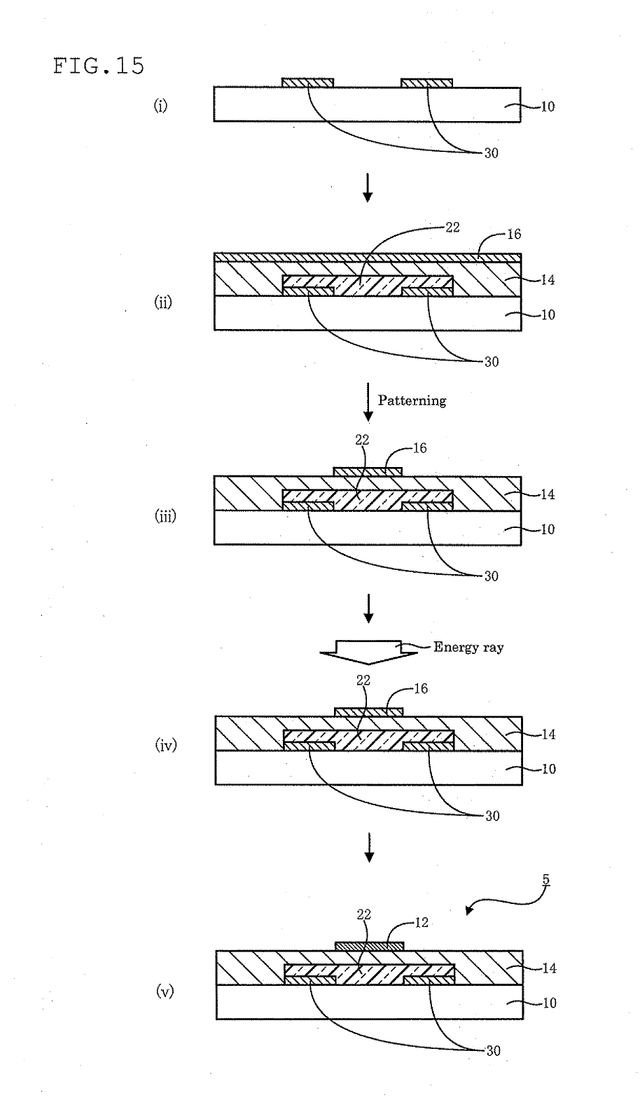

In the first and fourth embodiments, the heat-receiving film after heating is pattered to form an electrode. However, it is possible to pattern the heat-receiving film, followed by heating to form an electrode. FIG. 15 shows one embodiment in which a thin film transistor is produced by a process in which the heat-receiving film is patterned, and the patterned heat-receiving film is heated to form an electrode. The embodiment shown in FIG. 15 is similar to the fourth embodiment except that, after patterning, the heat-receiving film is heated to form an electrode.

When the heat-receiving film is heated after patterning to form an electrode, although the electrode obtained by heating the heat-receiving film may be any of the source electrode, the drain electrode and the gate electrode, the gate electrode is preferable. In the case where the heat-receiving film after patterning is heated, if the heat-receiving film after heating is not a gate electrode, the active layer part may not be heat-treated sufficiently.

In the invention, it is preferred that the source electrode and the drain electrode be transparent conductive films (ITO, IZO, ZnO, etc.) and the gate electrode be an electrode obtained by patterning and heating the heat-receiving film. If the source electrode and the drain electrode are electrodes obtained from the heat-receiving film, the temperature distribution during the heat treatment may be un-uniform.

The thin film transistor obtained by using the production method of the invention can be preferably used as a switching element and a sensor of a display panel such as a liquid crystal display and an electroluminescence display, for example.

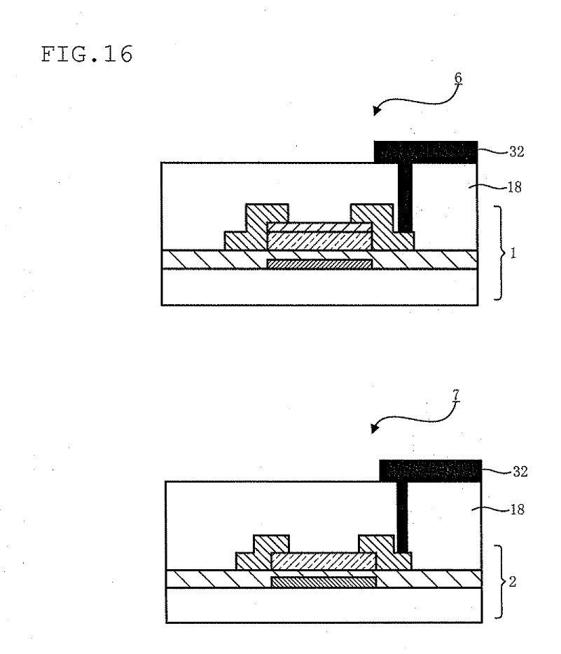

FIG. 16 is a schematic cross-sectional view of switching elements 6 and 7 obtained by forming a protective film 18 and a pixel electrode 32 in the thin film transistor 1 of the first embodiment and the thin film transistor 2 of the second embodiment. Since the thin film transistor 1 and the thin film transistor 2 are stable transistors suffering from only a small amount of shift in threshold value, a display panel using the switching element 6 and the switching element 7 does not undergo a change in properties even if used for a long time, and experiences only a slight change in display image quality. In addition, due to a high mobility, the thin film transistor of the invention has a high response speed, whereby it can be preferably used in a large-area, high-precision display.

The documents described in the specification are incorporated herein by reference in its entirety.

### EXAMPLES

The invention will be explained with reference to the examples. The following examples only show the preferred examples of the invention and should not be construed as limiting the scope of the invention. Accordingly, modifications or other examples based on the technical idea of the invention are included in the invention.

### First Aspect

### Example 1

Indium oxide with an average particle size of 2 μm and ZnO which had been pulverized to have an average diameter of about 1 to 2 μm were each weighted, and mixed such that indium oxide and ZnO had a composition ratio shown in Table 1. The mixture was then pulverized by means of a wet pulverizer for 24 hours. The resulting mixture was granulated by means of a spray dryer. The thus obtained granulated product was pressed into a predetermined size by means of a 2 t-pressing machine. The molded product obtained by the pressing was then molded at 200 MPa by means of an isostatic pressing machine. The resulting molded product was fired at 1380° C. for 24 hours while circulating oxygen. After the firing, cutting was conducted to obtain a sintered body with a diameter of 4 inches and a thickness of 5 mm. This sintered body was bonded to a backing plate with indium metal, thereby to form a sputtering target.

The resulting sputtering target was installed in a sputtering apparatus HSM 550 (manufactured by Shimadzu Corporation). In a 100% Ar atmosphere and under a pressure of 0.1 Pa, a 20 nm-thick amorphous thin film was formed on an Si wafer which was hard doped with an Sb atom and had a thermal oxide film (SiOn: 100 nm). The resulting Si wafer provided with the thin film was inserted into a scanning electron microscope, and was irradiated with an electron beam (20 kV accelerated electron) for 1 minute.

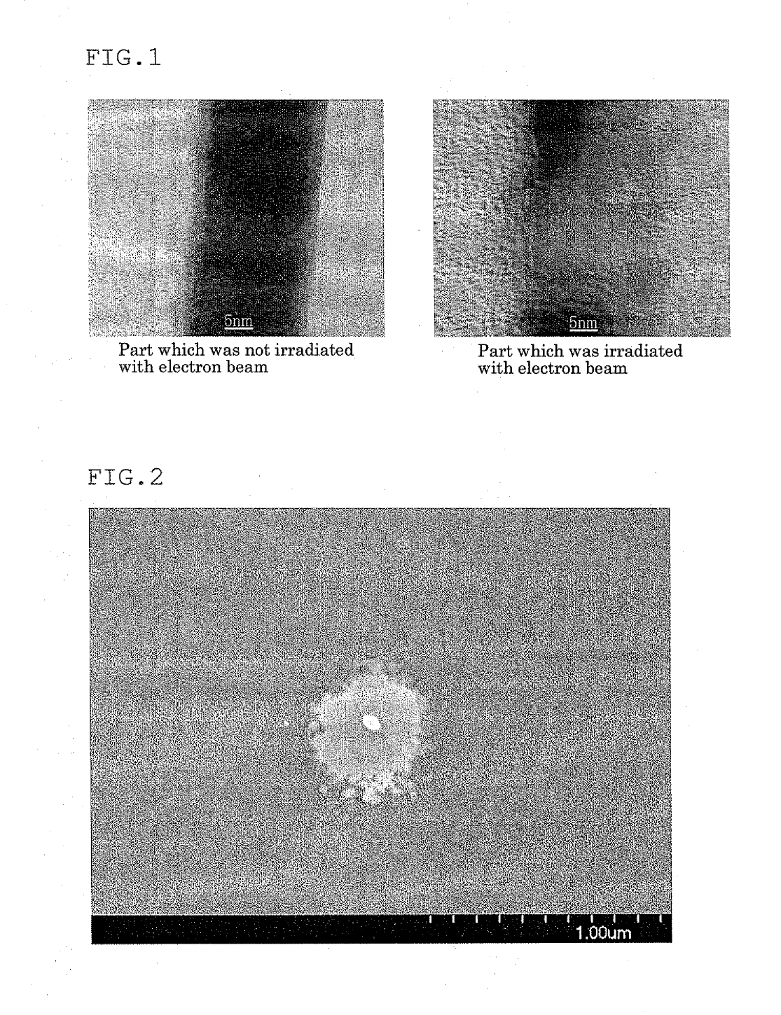

On the Si wafer provided with the thin film, which had been irradiated with the electron beam, carbon and tungsten were formed as a protective film. Then, a thin film segment was prepared by the FIB (first atomic bombardment) method, and the surface thereof was observed by means of a transmission electron microscope to confirm whether a crystalline region and an amorphous region were present. The photograph obtained is shown in FIG. 1. From the photograph, it can be confirmed that a crystal lattice was formed in a part irradiated with the electron beam, and that the irradiated part was crystallized.

The Si wafer provided with the thin film, which had been irradiated with the electron beam was immersed in a 2.38 wt % aqueous solution of oxalic acid for 3 minutes to etch the amorphous part thereof, whereby a patterned crystalline thin film was produced. For the crystallized part of the resulting patterned crystalline thin film, the carrier concentration was measured by the hall measurement. The results are shown in Table 1. From the results, it can be confirmed that the resulting crystalline thin film was a semiconductor thin film. The patterned crystalline thin film thus obtained was again inserted into the above-mentioned scanning electron microscope to observe the surface thereof. The photograph of the surface is shown in FIG. 2.

The hall measurement apparatus and the hall measurement conditions used in the above-mentioned hall measurement are as follows.

### [Hall Measurement Apparatus]

8310, manufactured by Toyo Technica Co., Ltd.

### [Measurement Conditions]

Resi Test Room temperature (about 25° C.), about 0.5 [T], about 10⁻⁴ to 10⁻¹² A, AC magnetic field hall measurement

### Examples 2 to 22

Sputtering targets were prepared in the same manner as in Example 1 in accordance with the composition ratios shown in Table 1, and crystalline thin films were formed and evaluated in the same manner as in Example 1. The results are shown in Table 1. The thin films of Examples 2 to 22 after the irradiation of an electron beam were observed in the same manner as in Example 1. As a result, it was confirmed that, in each film, only a part irradiated with an electron beam was crystallized.

A positive divalent metal oxide and a positive trivalent metal oxide used in the production of the sputtering targets each had an average particle size of 1 to 2 μm.

### Example 23

Indium oxide with an average particle site of 2 μm, ZnO which had been pulverized to have an average diameter of about 1 to 2 μm and gallium oxide with an average particle size of 2 μm were each weighted, and mixed such that indium oxide, ZnO and Ga₂O₃ had a composition ratio shown in Table 1. The mixture was then pulverized by means of a wet pulverizer for 24 hours. The resulting mixture was granulated by means of a spray dryer. The granulated product thus obtained was pressed into a predetermined size by means of a 2 t-pressing machine. The molded product obtained by the pressing was then molded at 200 MPa by means of an isostatic pressing machine. The resulting molded product was fired at 1380° C. for 24 hours while circulating oxygen. After the firing, cutting was conducted to obtain a sintered body with a diameter of 4 inches and a thickness of 5 mm. This sintered body was bonded to a backing plate with indium metal to form a sputtering target.

The resulting sputtering target was installed in a sputtering apparatus HSM 550 (manufactured by Shimadzu Corporation). In a 100% Ar atmosphere and under a pressure of 0.1 Pa, a 50 nm-thick amorphous thin film was formed on an Si wafer which was hard doped with an Sb atom and had a thermal oxide film (SiOn: 100 nm). The resulting Si wafer provided with the thin film was subjected to a laser annealing treatment by irradiating it with 1 pulse (pulse width=30 nsec.) of an excimer laser beam at an energy density of 150 mJ/cm² by means of a KrF laser with a wavelength of 248 nm. The Si wafer provided with the thin film after the irradiation of the excimer laser beam was observed in the same manner as in Example 1, and it was confirmed that only a part irradiated with the laser beam was crystallized.

The resulting Si wafer provided with the thin film after the irradiation of the excimer laser beam was etched in the same manner as in Example 1 to produce a patterned crystalline thin film. The carrier concentration of the patterned crystalline thin film thus obtained was measured in the same manner as in Example 1. The results are shown in Table 1. From the results, it was confirmed that the resulting patterned crystalline film was a semiconductor thin film.

TABLE 1

| | Composition of sputtering target | | | | | |
|---|---|---|---|---|---|---|
| | | Positive divalent | | Positive trivalent | | |
| | Indium oxide | metal oxide | | metal oxide | | Carrier |
| | Composition | | Composition | | Composition | concentration |
| | (wt %) | Type | (wt %) | Type | (wt %) | (/cm⁻³) |
| Example 1 | 95 | ZnO | 5 | | | 3.4E+16 |
| Example 2 | 97 | ZnO | 3 | | | 5.2E+16 |
| Example 3 | 99 | ZnO | 1 | | | 8.7E+16 |
| Example 4 | 99.5 | ZnO | 0.5 | | | 9.5E+16 |
| Example 5 | 97 | MgO | 3 | | | 4.0E+16 |
| Example 6 | 97 | NiO | 3 | | | 8.2E+15 |
| Example 7 | 97 | CuO | 3 | | | 6.2E+15 |
| Example 8 | 97 | | | B₂O₃ | 3 | 7.5E+16 |
| Example 9 | 97 | | | Ga₂O₃ | 3 | 1.2E+16 |
| Example 10 | 97 | | | Y₂O₃ | 3 | 2.3E+16 |
| Example 11 | 97 | | | Sc₂O₃ | 3 | 3.8E+16 |
| Example 12 | 97 | | | La₂O₃ | 3 | 2.2E+16 |
| Example 13 | 97 | | | Sm₂O₃ | 3 | 8.0E+15 |
| Example 14 | 97 | | | Nd₂O₃ | 3 | 6.8E+16 |
| Example 15 | 97 | | | Eu₂O₃ | 3 | 5.8E+16 |
| Example 16 | 97 | | | Gd₂O₃ | 3 | 2.3E+16 |
| Example 17 | 97 | | | Ho₂O₃ | 3 | 5.9E+16 |
| Example 18 | 97 | | | Er₂O₃ | 3 | 1.8E+16 |
| Example 19 | 95 | | | Yb₂O₃ | 5 | 8.6E+15 |
| Example 20 | 97 | | | Lu₂O₃ | 3 | 7.6E+15 |
| Example 21 | 97 | ZnO | 1 | Yb₂O₃ | 2 | 5.6E+15 |
| Example 22 | 97 | MgO | 1 | Yb₂O₃ | 2 | 3.7E+15 |
| Example 23 | 97 | MgO | 3 | Ga₂O₃ | 1 | 5.1E+15 |

### Second Aspect

### Example 24

A bottom-gate type field effect transistor of Embodiment 1 was produced.

### (1) Formation of a Substrate and a Gate Electrode

On a glass substrate, an MoW film (200 nm) was formed by magnetron DC sputtering.

In order to improve adhesiveness or the like, the film was treated with hexamethyldisilazane (HMDS). Thereafter, application of a resist, prebaking, light exposure using a mask with a gate electrode pattern, development (TMAH) and post baking were conducted for patterning.

After etching with a reactive ion etching (RIE), the resist was removed.

### (2) Formation of a Gate Insulating Film, an Amorphous Oxide Film, a Buffer Layer and a Light-Heat Conversion Film (a Film for Source/Drain Electrodes)

An SiNx gate insulating film (200 nm) was formed by plasma chemical vapor deposition (PECVD). Subsequently, without breaking vacuum, this film was sent to a sputtering chamber. In the sputtering chamber, an In₂O₃—ZnO film (In:Zn=97:3 in atomic ratio, 25 nm) was formed by magnetron DC sputtering. The resulting film was an amorphous conductive film having a specific resistance of 4×10⁻⁴ Ωcm. Further, the amorphous oxide film was patterned by photolithography and by wet etching using an oxalic acid-based etching solution. Thereafter, an SiO₂ film (200 nm) was formed by PECVD to form a buffer layer. On these films, an MoW film (200 nm) as a light-heat conversion film (a film for source/drain electrodes) was formed.

The specific resistance was measured by the four probe method. The film was confirmed to be amorphous by XRD.

### (3) Allowing the Film to be Semiconductive (Crystallization)

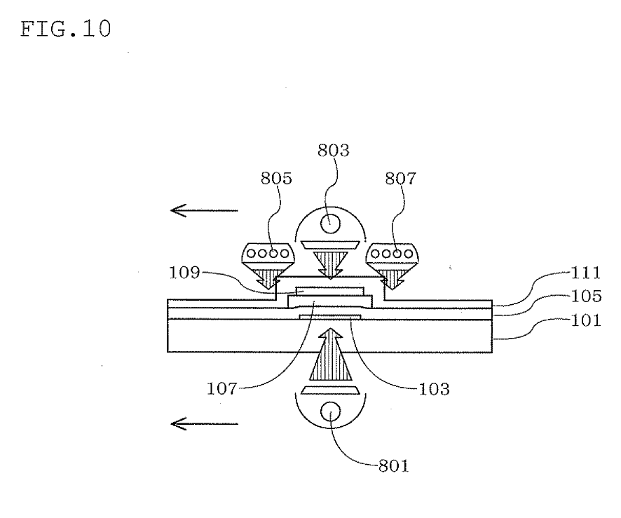

As shown in FIG. 10, an infrared tamp 801 was provided under the lower surface of a substrate 101 and an ultraviolet lamp 803 was provided above the upper surface of the substrate 101 (see FIGS. 3B and 3C). Further, in the front and back (relative to the moving direction of the substrate indicated by the arrow) of the ultraviolet lamp 803, a first auxiliary infrared lamp 805 and a second auxiliary infrared lamp 807 were arranged such that they were in parallel with the ultraviolet lamp 803. Both of the first auxiliary infrared lamp 805 and the second auxiliary infrared lamp 807 may be omitted. It is possible to arrange only one of them.

Each of the lamps 801, 803, 805 and 807 moved in the direction indicated by the arrow in the figure, and conducted liner light scanning. These lamps then moved to the front with the movement of the substrate 101. In this example, each lamp was caused to move when the substrate was irradiated with lamp light. It is possible to move the glass substrate or to move both the lamps and the substrate.

After the irradiation of light from the first auxiliary infrared lamp 805, irradiation of UV rays was conducted toward the upper surface of the substrate by means of the ultraviolet lamp 803. Further, irradiation of infrared rays were conducted toward the lower surface of the substrate by means of the infrared lamp 801, followed by irradiation of infrared rays by means of the second auxiliary infrared lamp 807. In this way, the region of the amorphous oxide film (conductive film) 107 was heated to be crystallized. The amorphous oxide film (conductive film) 107 which had reached a crystallization temperature underwent solid-phase crystallization, whereby a crystalline semiconductor film 113 was formed. The reason therefor is considered that, in combination with activation by heat, Zn as a dopant was activated to decrease the carrier density.

By XRD, it was confirmed that the film was crystallized (polycrystalline) and showed a bixbyite crystalline structure.

As mentioned above, since part of the oxide semiconductor film which was overlapped with the gate electrode is heated, shrinkage of the substrate can be prevented. Further, the throughput can be improved by conducting the crystallization step by moving each lamp or the substrate. In addition, the amorphous oxide film (conductive film) can be prevented from being heated quickly and the crystalline oxide semiconductor film can be prevented from being cooled quickly, and zinc as the dopant can be activated to change the conductive film into a semiconductor film. Also, stress strain and grain boundary defect which may occur during heating can be suppressed, whereby an oxide semiconductor film which is improved in crystalline properties can be obtained.

By conducting irradiation and heating without providing

the first auxiliary infrared lamp 805 and the second auxiliary infrared lamp 807, a heat applied on the substrate 101 may be suppressed.

In this embodiment, although an LRTA apparatus using a linear lamp was described, the crystallization may be conducted using a planar lamp.

The film obtained by the heating as mentioned above was a semiconductor film having a specific resistance of 4×10³ Ωcm.

### (4) Formation of Source/Drain Electrodes by Photolithography

Using photolithography, the film was patterned to have the shapes of source/drain electrodes.

The light-heat conversion film was etched by reactive ion etching (RIE) to form source/drain electrodes.

The resist was peeled off, whereby a bottom-gate type field effect transistor (thin film transistor) with a W/L of 2 (W=20 μm, L=10 μm) which was provided with a source electrode, a drain electrode, a gate electrode, an insulating film and a semiconductor film formed of a crystalline oxide was obtained.

### (5) Formation of a Protective Film and a Pixel Electrode

An SiNx protective film (300 nm) was formed by PECVD.

A contact hole was prepared to form a pixel electrode formed of an In₂O₃—ZnO transparent conductive film.

### (6) Evaluation of Transistor Properties

Using a semiconductor parameter analyzer (Keithley 4200), the mobility or the like of a field effect transistor were measured at room temperature and in the light-shielded environment.

Mobility: 10 cm²/Vs

On-off value: 10⁷

### Example 25

The field effect transistor of Embodiment 2 was prepared by using the same materials and method as in those in Example 24, except that no buffer layer was provided, SiO₂ was used as the protective film and a heat treatment was conducted at 300° C. for about 1 hour after the formation of the protective film.

### Example 26

The field effect transistor of Embodiment 3 was prepared by using the same materials and method as in those in Example 24.

### Example 27

The field effect transistor of Embodiment 4 was prepared by using the same materials and method as in those in Example 24.

An infrared lamp was used as the energy ray with a long wavelength, and an ultraviolet lamp was used as the energy ray with a short wavelength.

### Example 28

The field effect transistor of Embodiment 5 was prepared by using the same materials and method as in those in Example 27.

### Example 29

The field effect transistor of Embodiment 6 was prepared by using the same materials and the method as in those in Examples 27 and 28.

### Example 30

The field effect transistor of Embodiment 7 was prepared by using the same materials and the method as in those in Examples 24 to 26.

As the source electrode and the drain electrode, molybdenum (Mo) was used.

### Third Aspect

### Example 31

By the following steps which are the same as those in the first embodiment, a thin film transistor having the same configuration as that of the transistor 1 shown in FIG. 11 was prepared.

### [Preparation of a Substrate and Formation of a Gate Electrode]

On a silicon substrate provided with a thermal oxide film, an Mo gate metal was formed into a 200 nm-film by RF sputtering at room temperature, followed by patterning by wet etching.

### [Formation of a Gate Insulting Film, an Amorphous Oxide Film, a Protective Film and a Heat-Receiving Film]

Using a plasma chemical vapor growth method, a SiNx film was formed at 300° C. in a thickness of about 120 nm as a gate insulting film. A sintered target having an atomic ratio [In/(In+Zn+Al)] of 0.37, an atomic ratio [Zn/(In+Zn+Al)] of 0.55 and an atomic ratio [Al/(In+Zn+Al)] of 0.08 was installed in a RF magnetron sputtering film formation apparatus, and an amorphous oxide film with a thickness of 40 nm was formed on the gate insulating film. Regarding the composition of the amorphous oxide film, as a result of an ICP analysis, the amorphous oxide film was confirmed to have an atomic ratio [In/(In+Zn+Al)] of 0.38, an atomic ratio [Zn/(In+Zn+Al)] of 0.54 and an atomic ratio [Al/(In+Zn+Al)] of 0.08.

The sputtering conditions were as follows:

Substrate temperature (film forming temperature): 25° C.

Ultimate pressure: about 1×10⁻⁶ Pa

Atmospheric gas: Ar 99.5% and oxygen 0.5%

Sputtering pressure (total pressure): about 2×10⁻¹ Pa

Input power: about 100 W

Film forming time: 4 minutes

S-T distance: 80 mm

On the thus formed amorphous oxide film, SiO₂ was formed into a film of about 100 nm as the protective film. The protective film formed of SiO₂ also served as an etch stopper. A heat-receiving film formed of Mo was formed into a thickness of about 100 nm so as to cover the amorphous oxide film and the protective film.

An amorphous oxide film was separately formed in the same manner as mentioned above, and the crystallization temperature thereof was measured. It was found that the crystallization temperature of this film was about 700° C. As a result of XRD, the film was confirmed to be an amorphous film showing no clear peak.

### [Heat Treatment]

The heat-receiving film was heated for 30 seconds by means of an infrared lamp from above the heat-receiving film of the substrate, thereby to subject the amorphous oxide film to a heat treatment. The maximum temperature was assumed to be about 430° C.

### [Formation of Source/Drain Electrodes]

Using photolithography, the film was patterned to have the shapes of source/drain electrodes, whereby a bottom-gate type thin film transistor (W=24 μm and L=8 μm) was prepared.

### [Evaluation of a Transistor]

Using a semiconductor parameter analyzer (Keithley 4200, manufactured by Keithley instruments Inc.), the mobility (μ) of the thus formed thin film transistor was measured at room temperature, in the air, and in the light-shielded environment. As for adjacent 16 transistors, variations in on current (Ion) (σ of Ion/average value) was measured at plural parts of the substrate using a semiconductor parameter analyzer, and the average value thereof was calculated as the variation in current value. The results are shown in Table 2.

In order to evaluate the stability of the thus formed thin film transistor, using a semiconductor parameter analyzer, as a stress, a DC voltage of 3 μA was applied to the thus formed thin film transistor at 60° C. for 100 hours. The Vth before and after the application of the stress was compared, thereby to measure an amount of shift in threshold voltage (Δ Vth). The results are shown in Table 2.

### Example 32

A thin film transistor was prepared in the same manner as in Example 31, except that a buffer layer formed of SiO₂ was formed in a thickness of 20 nm instead of the protective film formed of SiO₂, and the heat-receiving film and the buffer layer were removed. As a result, a bottom-gate type thin film transistor (W=24 μm and L=8 μm) having a configuration similar to that of the thin film transistor 2 shown in FIG. 12 was prepared. The resulting thin film transistor was evaluated in the same manner as in Example 31. The results are shown in Table 2.

### Example 33

A top-gate type thin film transistor (W=24 μm and L=8 μm) having a configuration similar to that of the thin film transistor 3 shown in FIG. 13 was prepared in the same manner as in Example 32 except that the order of formation of each member was changed. The resulting thin film transistor was evaluated in the same manner as in Example 31. The results are shown in Table 2.

### Example 34

A top-gate type thin film transistor (W=24 μm and L=8 μm) having a configuration similar to that of the thin film transistor 4 shown in FIG. 14 was prepared in the same manner as in Example 31 except that the order of formation of each member was changed. The resulting thin film transistor was evaluated in the same manner as in Example 31. The results are shown in Table 2.

### Example 35

A thin film transistor (W=24 μm and L=8 μm) was prepared in the same manner as in Example 31 except that the heating of the heat-receiving film was conducted by means of a semiconductor laser instead of an infrared lamp. The resulting thin film transistor was evaluated in the same manner as in Example 31. The results are shown in Table 2.

As the laser light source of the semiconductor laser used in Example 35, a high-output, broad-area semiconductor laser apparatus with a wavelength of 808 nm was used. With this laser apparatus, a light output of about 4 W was obtained by continuous oscillation. In Example 5, a laser beam emitted from the above-mentioned semiconductor laser apparatus was passed through a uniform lightening optical system using microlens arrays or the like, and the beam was changed into a rectangular beam of which the light intensity profile on the long axis side was of flat-top hat type and the light intensity profile on the short axis side was of Gaussian type. This beam was condensed and irradiated on the heat-receiving film, and the substrate was moved at a constant speed of about 120 mm/s. Due to the irradiation of the semiconductor laser light, the molybdenum film was heated, and the heat was transmitted by heat conductance to the buffer layer and the amorphous oxide film which were below the molybdenum film, thereby allowing the amorphous oxide film to be heat-treated. Since the molybdenum film has a reflectance of about 56% for laser light having a wavelength of 808 nm, it is expected that energy in an amount of about 44% is absorbed in the film, thereby to contribute to annealing. The maximum temperature of the above-mentioned heat was assumed to be about 500° C.

### Example 36

A thin film transistor (W=24 μm and L=8 μm) was prepared in the same manner as in Example 31 except that the target used in the formation of the amorphous oxide film was changed such that the amorphous oxide thin film had a composition of an atomic ratio [In/(In+Zn+Ga)] of 0.33, an atomic ratio [Zn/(In+Zn+Ga)] of 0.34 and an atomic ratio [Ga/(In+Zn+Ga)] of 0.33. The resulting thin film transistor was evaluated in the same manner as in Example 31. The results are shown in Table 2.

### Example 37

A thin film transistor (W=24 μm and L=8 μm) was prepared in the same manner as in Example 37 except that the target used in the formation of the amorphous oxide film was changed such that the amorphous oxide thin film had a composition of an atomic ratio [In/(In+Zn+Ga)] of 0.4, an atomic ratio [Zn/(In+Zn+Ga)] of 0.2 and an atomic ratio [Ga/(In+Zn+Ga)] of 0.4. The resulting thin film transistor was evaluated in the same manner as in Example 37. The results are shown in Table 2.

### Example 38

A thin film transistor (W=24 μm and L=8 μm) was prepared in the same manner as in Example 1 except that the target used in the formation of the amorphous oxide film was changed such that the amorphous oxide thin film had a composition of an atomic ratio [Zn/(In+Sn)] of 0.5 and an atomic ratio [Sn/(Zn+Sn)] of 0.5. The resulting thin film transistor was evaluated in the same manner as in Example 31. The results are shown in Table 2.

### Comparative Example 1

A thin film transistor (W=24 μm and L=8 μm) was prepared in the same manner as in Example 31 except that the heat treatment using an infrared lamp was not conducted. The resulting thin film transistor was evaluated in the same manner as in Example 31. The results are shown in Table 2.

### Comparative Example 2

A thin film transistor (W=24 μm and L=8 μm) was prepared in the same manner as in Example 35 except that the heat treatment using a semiconductor laser was not conducted. The resulting thin film transistor was evaluated in the same manner as in Example 35. The results are shown in Table 2.

### Comparative Example 3

A thin film transistor (W=24 μm and L=8 μm) was prepared in the same manner as in Example 36 except that the heat treatment using an infrared lamp was not conducted. The resulting thin film transistor was evaluated in the same manner as in Example 36. The results are shown in Table 2.

### Comparative Example 4

A thin film transistor (W=24 μm and L=8 μm) was prepared in the same manner as in Example 37 except that the heat treatment using an infrared lamp was not conducted. The resulting thin film transistor was evaluated in the same manner as in Example 37. The results are shown in Table 2.

TABLE 2

| | Exam- | Exam- | Exam- | Exam- | Exam- | Exam- | Exam- | Exam- | Com. | Com. | Com. | Com. |
|---|---|---|---|---|---|---|---|---|---|---|---|---|
| | ple 31 | ple 32 | ple 33 | ple 34 | ple 35 | ple 36 | ple 37 | ple 38 | Ex. 1 | Ex. 2 | Ex. 3 | Ex. 4 |
| Channel width W | 24 | 24 | 24 | 24 | 24 | 24 | 24 | 24 | 24 | 24 | 24 | 24 |
| (μm) | | | | | | | | | | | | |
| Channel length L | 8 | 8 | 8 | 8 | 8 | 8 | 8 | 8 | 8 | 8 | 8 | 8 |
| (μm) | | | | | | | | | | | | |
| Mobility | 13 | 11 | 11 | 12 | 13 | 10 | 8 | 4 | 3 | 2 | 2 | 0.5 |
| (cm²/Vs) | | | | | | | | | | | | |
| S value | 0.2 | 0.3 | 0.3 | 0.3 | 0.2 | 0.4 | 0.5 | 0.5 | 0.8 | 0.9 | 1.0 | 1.5 |
| (V/dec) | | | | | | | | | | | | |
| Variation in | 1.4 | 2.1 | 2.1 | 1.5 | 1.7 | 1.6 | 1.5 | 1.6 | 2.4 | 2.6 | 2.5 | 2.9 |
| current value | | | | | | | | | | | | |
| (%) | | | | | | | | | | | | |
| Shift amount of | 0.1 | 0.5 | 0.5 | 0.1 | 0.1 | 0.2 | 0.3 | 0.9 | 2.8 | 3.1 | 3.3 | 4.2 |
| threshold voltage | | | | | | | | | | | | |
| (V) | | | | | | | | | | | | |
| XRD | Amor- | Amor- | Amor- | Amor- | Amor- | Amor- | Amor- | Amor- | Amor- | Amor- | Amor- | Amor- |
| | phous | phous | phous | phous | phous | phous | phous | phous | phous | phous | phous | phous |

### INDUSTRIAL APPLICABILITY

The patterned crystalline semiconductor film as the first aspect of the invention can be preferably used as a thin film transistor for a LCD or a thin film transistor for an organic electroluminescence (EL) device. In particular, since the semiconductor thin film of the invention is formed of an oxide, when used as a thin film transistor for a current-controlled organic EL device, it functions as a highly durable thin film transistor.

The thin film transistor as the second aspect of the invention can be applied to an integrated circuit such as a logical circuit, a memory circuit, and a differential amplification circuit. In particular, the thin film transistor can be preferably used as a switching element for driving a liquid crystal display or an organic EL display.

A thin film transistor obtained by the production method according to the third aspect of the invention has transistor properties which are suitable for displays such as flat displays.

1. A patterned crystalline semiconductor thin film which is obtained by a method comprising:
forming an amorphous thin film comprising indium oxide as a main component,
crystallizing part of the amorphous thin film to allow the part to be semiconductive, and
removing an amorphous part of the partially crystallized thin film by etching.

2. The patterned crystalline semiconductor thin film according to claim 1, wherein the amorphous thin film comprises indium oxide containing a positive divalent metal oxide.

3. The patterned crystalline semiconductor thin film according to claim 1, wherein the amorphous thin film comprises indium oxide containing a positive trivalent metal oxide.

4. The patterned crystalline semiconductor thin film according to claim 1, wherein the amorphous thin film comprises indium oxide containing a positive divalent metal oxide and a positive trivalent metal oxide.

5. The patterned crystalline semiconductor film according to claim 1, wherein the crystallization is conducted by using an electron beam.

6. The patterned crystalline semiconductor film according to claim 1, wherein the crystallization is conducted by using a laser beam.

7. The patterned crystalline semiconductor film according to claim 5, wherein the method further comprises conducting a heat treatment after the etching.

8. A method for producing a thin film transistor comprising the steps of:
forming an amorphous oxide film,
forming a light-heat conversion film on the amorphous oxide film, and
irradiating the light-heat conversion film with an energy ray to allow at least part of the amorphous oxide film to be semiconductive.

9. The method for producing a thin film transistor according to claim 8, wherein the amorphous oxide film is conductive, and when at least part of the amorphous oxide film is allowed to be semiconductive by irradiating the light-heat conversion film with an energy ray, the part is crystallized.

10. The method for producing a thin film transistor according to claim 8, which further comprises the step of patterning the amorphous oxide film to form a source electrode and a drain electrode.

11. The method for producing a thin film transistor according to claim 8, which further comprises the step of patterning the light-heat conversion film to form a source electrode and a drain electrode.

12. The method for producing a thin film transistor according to claim 8, which further comprises the step of removing the light-heat conversion film.

13. The method for producing a thin film transistor according to claim 8, which further comprises the step of providing a buffer film between the amorphous oxide film and the light-heat conversion film.

14. The method for producing a thin film transistor according to claim 8, wherein the energy ray is semiconductor laser light or lamp light.

15. The method for producing a thin film transistor according to claim 8, wherein the amorphous oxide film comprises at least In.

16. The method for producing a thin film transistor according to claim 8, wherein the amorphous oxide film comprises a composite metal oxide which contains In, and a positive divalent element or a positive trivalent element.

17. A field effect transistor comprising:
a gate electrode,
a layer which is on the gate electrode and is formed of a source electrode, a drain electrode and a semiconductor film, and
a buffer film and a light-heat conversion film which are on the semiconductor film, wherein
the semiconductor film is a film which is obtained by crystallizing an oxide which forms the source electrode and the drain electrode.

18. A field effect transistor comprising:
a source electrode and a drain electrode,
a semiconductor film which is on the source electrode and the drain electrode, and comprises a crystalline oxide,
a gate insulating film which is on the semiconductor film, and
a gate electrode which is on the gate insulating film.

19. A method for producing a thin film transistor which comprises the steps of:
forming an amorphous oxide film,
forming a heat-receiving film, and
heating the heat-receiving film.

20. The method for producing a thin film transistor according to claim 19, which further comprises the step of patterning the heat-receiving film to form at least one of a source electrode, a drain electrode and a gate electrode.

21. The method for producing a thin film transistor according to claim 19, which further comprises the step of stacking a buffer layer and the step of removing the heat-receiving film and the buffer layer.

22. The method for producing a thin film transistor according to claim 19, wherein the heat-receiving film is heated by a heating method selected from the group consisting of infrared lamp heating, ultraviolet lamp heating, semiconductor laser heating, excimer laser heating, an electromagnetic induction heating and plasma jet heating.

23. The method for producing a thin film transistor according to claim 19, wherein the heat treatment of the amorphous oxide film is conducted at a temperature equal to or higher than the film forming temperature of the amorphous oxide film, and equal to or lower than the crystallization temperature of the amorphous oxide film.

24. The method for producing a thin film transistor according to claim 19, wherein the amorphous oxide film comprises one or more elements selected from the group consisting of In, Zn and Sn.

25. A thin film transistor which is obtained by the method for producing a thin film transistor according to claim 19.
